(19) United States
(12) Patent Application Publication
(10) Pub. No.: US 2025/0239475 A1
(43) Pub. Date: Jul. 24, 2025

(54) CONVEYANCE APPARATUS, TRANSFER METHOD, CONVEYANCE METHOD, AND SEMICONDUCTOR APPARATUS MANUFACTURING METHOD

(71) Applicant: JSW Aktina System Co., Ltd., Yokohama-shi, Kanagawa (JP)

(72) Inventors: Takahiro FUJI, Yokohama-shi, Kanagawa (JP); Ryo SHIMIZU, Yokohama-shi, Kanagawa (JP); Mitsuhiro SATOU, Yokohama-shi, Kanagawa (JP)

(73) Assignee: JSW Aktina System Co., Ltd., Yokohama-shi, Kanagawa (JP)

(21) Appl. No.: 18/853,548

(22) PCT Filed: Apr. 14, 2022
(86) PCT No.: PCT/JP2022/017848

§ 371 Date: Oct. 2, 2024

(51) Int. Cl. H01L 21/677; H01L 21/268; H01L 21/67; H01L 21/683

(52) U.S. Cl. CPC H01L 21/67787; H01L 21/268; H01L 21/67115; H01L 21/67742; H01L 21/67745; H01L 21/6838

(57) ABSTRACT

A conveyance apparatus according to the present embodiment is a conveyance apparatus configured to convey a substrate to irradiate the substrate with a linear laser beam and includes: a levitation unit including a loading region into which the substrate is loaded; a first holding mechanism configured to hold the substrate over the levitation unit; a first moving mechanism configured to move the first holding mechanism in a first conveyance direction; a plurality of pusher pins disposed in the loading region of the levitation unit and provided to be movable upward and downward to receive the substrate from a transfer machine transferring the substrate; and a rotary mechanism disposed among the plurality of pusher pins in the loading region of the levitation unit and configured to rotate the substrate.

### TECHNICAL FIELD

The present invention relates to a conveyance apparatus, a transfer method, a conveyance method, and a semiconductor apparatus manufacturing method.

### BACKGROUND ART

A laser anneal apparatus for forming a polycrystalline silicon thin film is disclosed in Patent Literature 1. In Patent Literature 1, a projection lens focuses a laser beam onto a substrate so that the laser beam forms a linear irradiation region. Accordingly, an amorphous silicon film is crystallized into a poly-silicon film.

In Patent Literature 1, the conveyance unit conveys the substrate in a state in which a levitation unit levitates the substrate. Further, a loading position and an unloading position of the substrate are the same at the levitation unit. The conveyance unit conveys the substrate along each side of the levitation unit. The substrate circulates over the levitation unit twice, and accordingly, substantially the entire surface of the substrate is irradiated with a laser beam.

### CITATION LIST

### Patent Literature

[Patent Literature 1] Japanese Unexamined Patent Application Publication No. 2018-64048

### SUMMARY OF INVENTION

In such a conveyance apparatus of a laser irradiation apparatus, a substrate is desired to be conveyed appropriately so that a laser irradiation process is stably executed at high speed.

Other problems and novel features will become apparent from the description and accompanying drawings of the present specification.

According to an embodiment, a conveyance apparatus is a conveyance apparatus configured to convey a substrate to irradiate the substrate with a linear laser beam and includes: a levitation unit including a loading region into which a substrate is loaded, the levitation unit being configured to levitate the substrate over an upper surface of the levitation unit; a first holding mechanism configured to hold the substrate over the levitation unit; a first moving mechanism configured to move the first holding mechanism in a first conveyance direction tilted from a line direction of the laser beam when viewed from top to change an irradiation position of the laser beam on the substrate; a plurality of pusher pins disposed in the loading region of the levitation unit and provided to be movable upward and downward to receive the substrate from a transfer machine transferring the substrate; and a rotary mechanism disposed among the plurality of pusher pins in the loading region of the levitation unit and configured to rotate the substrate.

According to an embodiment, a conveyance apparatus is a conveyance apparatus configured to convey a substrate to irradiate the substrate with a linear laser beam and includes: a levitation unit including a loading region into which a substrate is loaded, the levitation unit being configured to levitate the substrate over an upper surface of the levitation unit; a first holding mechanism configured to hold the substrate over the levitation unit; a first moving mechanism configured to move the first holding mechanism in a first conveyance direction tilted from a line direction of the laser beam when viewed from top to change an irradiation position of the laser beam on the substrate; a plurality of pusher pins disposed in the loading region of the levitation unit and provided to be movable upward and downward to receive the substrate from a transfer machine transferring the substrate; an end part levitation unit disposed on the transfer machine side of the levitation unit and configured to levitate an end part of the substrate over an upper surface of the end part levitation unit; a pusher bar extending in a transfer direction of the transfer machine and configured to move upward and downward in coordination with the pusher pins to receive the substrate from the transfer machine; a second holding mechanism disposed between the end part levitation unit and the end part levitation unit and configured to hold the substrate; and a second holding mechanism configured to move the second holding mechanism in a second conveyance direction so that the second holding mechanism moves between the end part levitation unit and the end part levitation unit.

According to an embodiment, a conveyance apparatus is a conveyance apparatus configured to convey a substrate to irradiate the substrate with a linear laser beam and includes: a levitation unit including a plurality of levitation unit cells and configured to levitate the substrate over an upper surface of the levitation unit; a holding mechanism configured to hold the substrate over the levitation unit; a moving mechanism configured to move the holding mechanism in a conveyance direction tilted from a line direction of the laser beam when viewed from top to change an irradiation position of the laser beam on the substrate; and a nozzle unit provided in a gap between the levitation unit cells adjacent to each other and configured to eject gas toward an end part of the substrate.

According to an embodiment, a transfer method is a transfer method of transferring a substrate to a conveyance apparatus configured to convey the substrate to irradiate the substrate with a linear laser beam, in which: the conveyance apparatus includes a levitation unit including a loading region into which a substrate is loaded, the levitation unit being configured to levitate the substrate over an upper surface of the levitation unit, a first holding mechanism configured to hold the substrate over the levitation unit, a first moving mechanism configured to move the first holding mechanism in a first conveyance direction tilted from a line direction of the laser beam when viewed from top to change an irradiation position of the laser beam on the substrate, a plurality of pusher pins disposed in the loading region of the levitation unit and provided to be movable upward and downward to receive the substrate from a transfer machine transferring the substrate, and a rotary mechanism disposed among the plurality of pusher pins in the loading region of the levitation unit and configured to rotate the substrate; and the transfer method includes (A1) step of moving the plurality of pusher pins upward to receive a substrate loaded into the loading region by the transfer machine, (A2) step of moving the transfer machine to a standby position outside the loading region, and (A3) step of moving the plurality of pusher pins downward to move the substrate downward to a levitation height of the levitation unit.

According to an embodiment, a transfer method is a transfer method of transferring a substrate to a conveyance apparatus configured to convey the substrate to irradiate the substrate with a linear laser beam, in which: the conveyance apparatus includes a levitation unit including a loading region into which a substrate is loaded, the levitation unit being configured to levitate the substrate over an upper surface of the levitation unit, a first holding mechanism configured to hold the substrate over the levitation unit, a first moving mechanism configured to move the first holding mechanism in a first conveyance direction tilted from a line direction of the laser beam when viewed from top to change an irradiation position of the laser beam on the substrate, a plurality of pusher pins disposed in the loading region of the levitation unit and provided to be movable upward and downward to receive the substrate from a transfer machine transferring the substrate, an end part levitation unit disposed on the transfer machine side of the levitation unit and configured to levitate an end part of the substrate over an upper surface of the end part levitation unit, a pusher bar extending in a transfer direction of the transfer machine and configured to move upward and downward in coordination with the pusher pins to receive the substrate from the transfer machine, a second holding mechanism disposed between the end part levitation unit and the end part levitation unit and configured to hold the substrate, and a second holding mechanism configured to move the second holding mechanism in a second conveyance direction 10 so that the second holding mechanism moves between the end part levitation unit and the end part levitation unit; and the transfer method includes (B1) step of moving the plurality of pusher pins and the pusher bar upward to receive the substrate loaded into the loading region by the transfer machine, (B2) step of moving the transfer machine to a standby position outside the loading region, and (B3) step of moving the plurality of pusher pins and the pusher bar downward to move the substrate downward to a levitation height of the levitation unit.

According to an embodiment, a conveyance method is a conveyance method of conveying a substrate by using a conveyance apparatus to irradiate the substrate with a linear laser beam, in which: the conveyance apparatus includes a levitation unit including a plurality of levitation unit cells and configured to levitate the substrate over an upper surface of the levitation unit, a holding mechanism configured to hold the substrate over the levitation unit, a moving mechanism configured to move the holding mechanism in a conveyance direction tilted from a line direction of the laser beam when viewed from top to change an irradiation position of the laser beam on the substrate, and a nozzle unit provided in a gap between the levitation unit cells adjacent to each other and configured to eject gas toward an end part of the substrate; and the conveyance method includes (C1) step of moving the holding mechanism by the moving mechanism to convey the substrate in a conveyance direction, and (C2) step of ejecting, by the nozzle unit, gas to an end part of the substrate being conveyed.

According to an embodiment, a semiconductor apparatus manufacturing method includes (s1) step of forming an amorphous film on a substrate, (s2) step of transferring the substrate on which the amorphous film is formed to a conveyance apparatus, and (s3) step of annealing the amorphous film by irradiating the substrate with a linear laser beam while conveying the substrate by using the conveyance apparatus so that the amorphous film is crystallized to form a crystallized film; the conveyance apparatus includes a levitation unit including a loading region into which a substrate is loaded, the levitation unit being configured to levitate the substrate over an upper surface of the levitation unit, a first holding mechanism configured to hold the substrate over the levitation unit, a first moving mechanism configured to move the first holding mechanism in a first conveyance direction tilted from a line direction of the laser beam when viewed from top to change an irradiation position of the laser beam on the substrate, a plurality of pusher pins disposed in the loading region of the levitation unit and provided to be movable upward and downward to receive the substrate from a transfer machine transferring the substrate, and a rotary mechanism disposed among the plurality of pusher pins in the loading region of the levitation unit and configured to rotate the substrate; and (s2) the transferring step includes (sa1) step of moving the plurality of pusher pins upward to receive a substrate loaded into the loading region by the transfer machine, (sa2) step of moving the transfer machine to a standby position outside the loading region, and (sa3) step of moving the plurality of pusher pins downward to move the substrate downward to a levitation height of the levitation unit.

According to an embodiment, a semiconductor apparatus manufacturing method includes (s1) step of forming an amorphous film on a substrate, (s2) step of transferring the substrate on which the amorphous film is formed to a conveyance apparatus, and (s3) step of annealing the amorphous film by irradiating the substrate with a linear laser beam while conveying the substrate by using the conveyance apparatus so that the amorphous film is crystallized to form a crystallized film; the conveyance apparatus includes a levitation unit including a loading region into which a substrate is loaded, the levitation unit being configured to levitate the substrate over an upper surface of the levitation unit, a first holding mechanism configured to hold the substrate over the levitation unit, a first moving mechanism configured to move the first holding mechanism in a first conveyance direction tilted from a line direction of the laser beam when viewed from top to change an irradiation position of the laser beam on the substrate, a plurality of pusher pins disposed in the loading region of the levitation unit and provided to be movable upward and downward to receive the substrate from a transfer machine transferring the substrate, an end part levitation unit disposed on the transfer machine side of the levitation unit and configured to levitate an end part of the substrate over an upper surface of the end part levitation unit, a pusher bar extending in a transfer direction of the transfer machine and configured to move upward and downward in coordination with the pusher pins to receive the substrate from the transfer machine, a second holding mechanism disposed between the end part levitation unit and the end part levitation unit and configured to hold the substrate, and a second holding mechanism configured to move the second holding mechanism in a second conveyance direction so that the second holding mechanism moves between the end part levitation unit and the end part levitation unit; and the semiconductor apparatus manufacturing method includes (sb1) step of moving the plurality of pusher pins and the pusher bar upward to receive the substrate loaded into the loading region by the transfer machine, (sb2) step of moving the transfer machine to a standby position outside the loading region, and (sb3) step of moving the plurality of pusher pins and the pusher bar downward to move the substrate downward to a levitation height of the levitation unit.

According to an embodiment, a semiconductor apparatus manufacturing method includes (t1) step of forming an amorphous film on a substrate, (t2) step of conveying the substrate on which the amorphous film is formed by using a conveyance apparatus, and (t3) step of annealing the amorphous film by irradiating the substrate being conveyed by the conveyance apparatus with a linear laser beam so that the amorphous film is crystallized to form a crystallized film; the conveyance apparatus includes a levitation unit including a plurality of levitation unit cells and configured to levitate the substrate over an upper surface of the levitation unit, a holding mechanism configured to hold the substrate over the levitation unit, a moving mechanism configured to move the holding mechanism in a conveyance direction tilted from a line direction of the laser beam when viewed from top to change an irradiation position of the laser beam on the substrate, and a nozzle unit provided in a gap between the levitation unit cells adjacent to each other and configured to eject gas toward an end part of the substrate; and the (t2) conveying step includes (tc1) step of moving the holding mechanism by the moving mechanism to convey the substrate in a conveyance direction, and (tc2) step of ejecting, by the nozzle unit, gas to an end part of the substrate being conveyed.

According to an embodiment, substrate conveyance suitable for a laser irradiation process can be achieved.

### BRIEF DESCRIPTION OF DRAWINGS

FIG. 1 is a top view schematically illustrating the configuration of a conveyance apparatus used for a laser irradiation apparatus;

FIG. 2 is a side cross-sectional view schematically illustrating the laser irradiation apparatus;

FIG. 3 is a top view schematically illustrating a detailed configuration of the conveyance apparatus;

FIG. 4 is a top view for description of the process of conveyance by the conveyance apparatus;

FIG. 5 is a top view for description of the process of conveyance by the conveyance apparatus;

FIG. 6 is a top view for description of the process of conveyance by the conveyance apparatus;

FIG. 7 is a top view for description of the process of conveyance by the conveyance apparatus;

FIG. 8 is a top view for description of the process of conveyance by the conveyance apparatus;

FIG. 9 is a top view for description of the process of conveyance by the conveyance apparatus;

FIG. 10 is a top view for description of the process of conveyance by the conveyance apparatus;

FIG. 11 is a top view for description of the process of conveyance by the conveyance apparatus;

FIG. 12 is a side cross-sectional view illustrating disposition of a nozzle unit in the conveyance apparatus;

FIG. 13 is a diagram illustrating the configuration of the nozzle unit;

FIG. 14 is a diagram illustrating the configuration of the nozzle unit according to a modification;

FIG. 15 is a top view illustrating an arrangement example of nozzle units;

FIG. 16 is a top view illustrating an arrangement example 3 of nozzle units;

FIG. 17 is a diagram illustrating height difference between an end part levitation unit and a levitation unit;

FIG. 18 is a diagram illustrating a modification of the end part levitation unit;

FIG. 19 is a top view schematically illustrating a base having release holes;

FIG. 20 is a side view schematically illustrating the base having release holes;

FIG. 21 is a top view for description of substrate loading operation;

FIG. 22 is a top view for description of substrate loading operation;

FIG. 23 is a top view for description of substrate loading operation;

FIG. 24 is a side view for description of upward-downward movement operation of pusher pins;

FIG. 25 is a top view schematically illustrating a configuration including pusher bars;

FIG. 26 is a side view for description of upward-downward movement operation of the pusher bars;

FIG. 27 is a top view schematically illustrating a modification of the configuration including pusher bars;

FIG. 28 is a cross-sectional view illustrating the configuration of an organic light-emitting diode display in a simplified manner;

FIG. 29 is a process cross-sectional view illustrating a semiconductor apparatus manufacturing method according to the present embodiment; and

FIG. 30 is a process cross-sectional view illustrating the semiconductor apparatus manufacturing method according to the present embodiment.

### DESCRIPTION OF EMBODIMENTS

A conveyance apparatus according to the present embodiment is used for a laser irradiation apparatus such as a laser anneal apparatus. The laser anneal apparatus is, for example, an excimer laser anneal (ELA) apparatus that forms a low temperature poly-silicon (LTPS) film. A conveyance apparatus, a laser irradiation apparatus, a method, and a manufacturing method according to the present embodiment will be described below with reference to the accompanying drawings.

### Embodiment 1

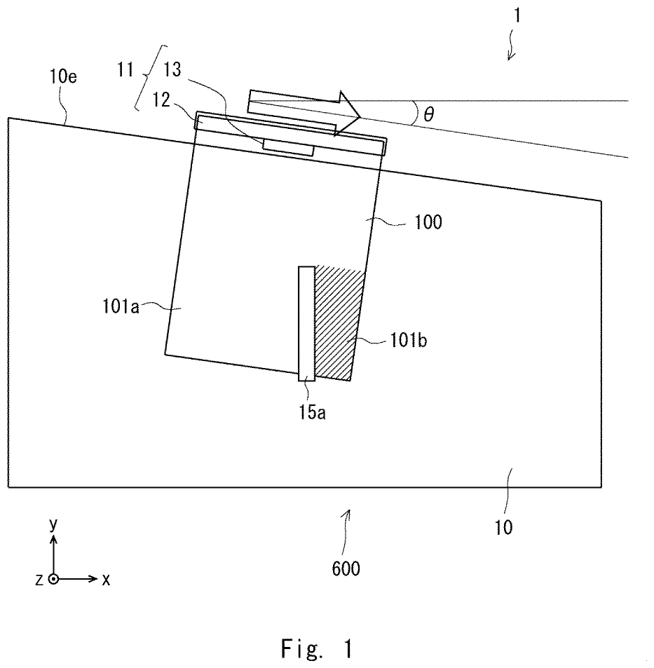

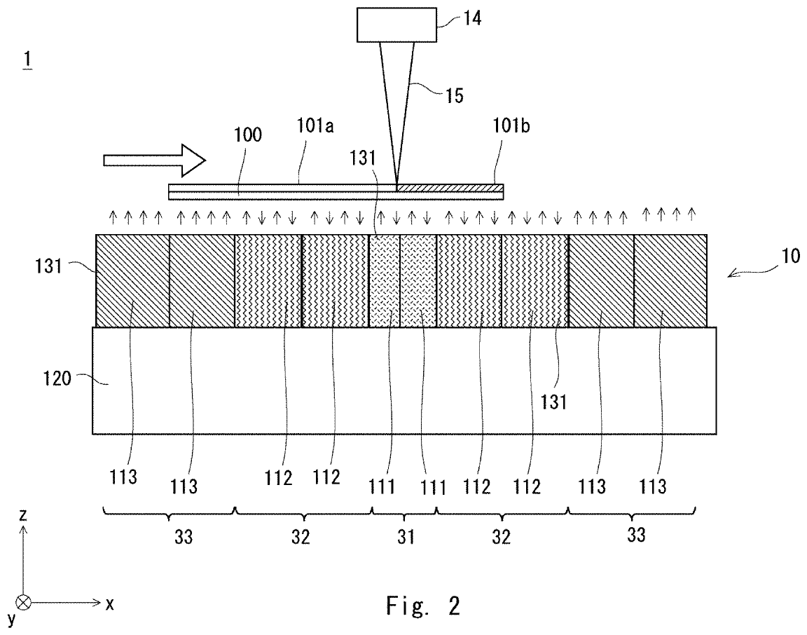

Basic configurations of the conveyance apparatus and the laser irradiation apparatus according to the present embodiment will be described below with reference to FIGS. 1 and 2. FIG. 1 is a top view schematically illustrating a basic configuration of a laser irradiation apparatus 1. FIG. 2 is a side cross-sectional view schematically illustrating the configuration of the laser irradiation apparatus 1.

Note that FIGS. 1 and 2 are conceptual diagrams illustrating only the basic configurations of the conveyance apparatus and the laser irradiation apparatus, and some components are omitted. For example, a conveyance apparatus 600 is illustrated in a simplified manner in FIG. 1. Specifically, a laser irradiation unit 14, a precise levitation region 31, a semi-precise levitation region 32, a rough levitation region 33, a precise levitation unit 111, a semi-precise levitation unit 112, and a rough levitation unit 113 are omitted in FIG. 1.

Note that, in diagrams described below, an xyz three-dimensional orthogonal coordinate system is illustrated as appropriate for simplification of explanation. The z direction is the vertical direction, and the y direction is a line direction along a linear irradiation region 15a. The x direction is a direction orthogonal to the z direction and the y direction. Accordingly, the y direction is the longitudinal direction of the linear irradiation region 15a, and the x direction is a transverse direction orthogonal to the longitudinal direction.

As illustrated in FIGS. 1 and 2, the laser irradiation apparatus 1 includes a levitation unit 10, a conveyance unit 11, and the laser irradiation unit 14. The levitation unit 10 and the conveyance unit 11 constitute the conveyance apparatus 600.

As illustrated in FIG. 2, the levitation unit 10 is configured to eject gas from a surface of the levitation unit 10. The levitation unit 10 levitates a substrate 100 over its upper surface. The substrate 100 is levitated as gas ejected from the surface of the levitation unit 10 is blown to a lower surface of the substrate 100. The substrate 100 is, for example, a glass substrate. When the substrate 100 is conveyed, the levitation unit 10 adjusts the amount of levitation so that the substrate 100 does not contact another mechanism (not illustrated) disposed on the upper side of the substrate 100.

The levitation unit 10 is mainly divided into the precise levitation region 31, the semi-precise levitation region 32, and the rough levitation region 33. The precise levitation region 31 is a region including the irradiation region 15a of a laser beam 15. In other words, the precise levitation region 31 is a region that overlaps the focal point (irradiation region 15a) of the laser beam in an xy plan view. The precise levitation region 31 is a region larger than the irradiation region 15a.

The semi-precise levitation region 32 is a region adjacent to the precise levitation region 31. The semi-precise levitation region 32 is disposed on both sides of the precise levitation region 31 in the x direction. Each semi-precise levitation region 32 is a region larger than the precise levitation region 31.

The rough levitation region 33 is a region adjacent to one of the semi-precise levitation regions 32. Specifically, the semi-precise levitation region 32 is disposed between the rough levitation region 33 and the precise levitation region 31. The rough levitation region 33 is disposed on both sides of the precise levitation region 31 in the X direction. In other words, the rough levitation regions 33 are disposed separately on the +x side and the −x side of the semi-precise levitation regions 32. The semi-precise levitation regions 32 and the rough levitation regions 33 are regions that do not overlap the focal point (irradiation region 15a) of the laser beam in an xy plan view.

The precise levitation unit 111, the semi-precise levitation unit 112, and the rough levitation unit 113 each eject gas (for example, air) upward. The gas ejected from the precise levitation unit 111, the semi-precise levitation unit 112, and the rough levitation unit 113 may be inert gas such as nitrogen. The substrate 100 is levitated as the gas blows onto the lower surface of the substrate 100. Accordingly, the levitation unit 10 and the substrate 100 become a non-contact state. In addition, the precise levitation unit 111 and the semi-precise levitation unit 112 suck gas existing between the substrate 100 and the levitation unit 10. The rough levitation unit 113 as well as the semi-precise levitation unit 112 are configured to be able to suck gas.

For example, a gas supply source (not illustrated) for supplying gas is connected to the precise levitation unit 111, the semi-precise levitation unit 112, and the rough levitation unit 113. In addition, a vacuum generation source (not illustrated) for sucking gas is connected to the precise levitation unit 111, the semi-precise levitation unit 112, and the rough levitation unit 113. The gas supply source is a compressor, a gas tank, or the like and supplies compressed gas. The vacuum generation source is a vacuum pump, an ejector, or the like.

The precise levitation unit 111 has a higher accuracy of levitation amount than the semi-precise levitation unit 112 and the rough levitation unit 113. The semi-precise levitation unit 112 has a higher accuracy of levitation amount than the rough levitation unit 113. The substrate 100 is irradiated with a laser beam in the precise levitation region 31 having the highest accuracy of levitation amount. For example, the semi-precise levitation unit 112 is configured to levitate the substrate 100 at accuracy between accuracy when the precise levitation unit 111 levitates the substrate 100 and accuracy when the rough levitation unit 113 levitates the substrate 100.

For example, high accuracy is requested for the amount of levitation of the substrate 100 in the irradiation region 15a and the precise levitation region 31 around the irradiation region 15a. Thus, the precise levitation unit 111 capable of controlling the amount of levitation at high accuracy is used. The precise levitation unit 111 is a precise levitation unit formed of a porous body such as ceramic. Porous alumina ceramic, porous carbon, porous SiC ceramic, or the like can be used as the porous body.

The precise levitation unit 111 ejects gas upward. The precise levitation unit 111 may be provided with suction holes for sucking gas. The porous body is fabricated with suction holes reaching the upper surface at predetermined intervals. The suction holes are minute holes and form negative pressure between the substrate 100 and the precise levitation unit. The porous body ejects gas from substantially the entire surface except for the suction holes. An ejection surface that forms positive pressure is formed at substantially the entire surface except for the suction holes.

The semi-precise levitation unit 112 and the rough levitation unit 113 are formed of a metallic material. For example, the semi-precise levitation unit 112 and the rough levitation unit 113 are formed of a metal block having a hollow part. In addition, a plurality of ejection holes from the hollow part to the upper surface of the metal block are formed. The metal block may be additionally provided with suction holes that suck gas. Note that any one of the semi-precise levitation unit 112 and the rough levitation unit 113 may be omitted.

The rough levitation unit 113, the semi-precise levitation unit 112, and the precise levitation unit 111 are also collectively referred to as a levitation unit cell 131. A plurality of rough levitation units 113 are provided as levitation unit cells 131 in each rough levitation region 33. A plurality of semi-precise levitation units 112 are provided as levitation unit cells 131 in each semi-precise levitation region 32. A plurality of precise levitation units 111 are provided as levitation unit cells 131 in the precise levitation region 31.

A base 120 is, for example, a metal plate made of aluminum or made of aluminum alloy. The precise levitation units 111, the semi-precise levitation units 112, and the rough levitation units 113 are fixed to the base 120 by, for example, bolts. The upper surfaces of the precise levitation units 111, the semi-precise levitation units 112, and the rough levitation units 113 are at the same height in effect. In other words, the upper surface (levitation surface) of the levitation unit 10 is flat in effect. The surface of the base 120 may be provided with polishing fabrication or the like to have a predetermined flatness. In addition, an internal space (not illustrated) serving as a flow path for ejecting or sucking gas may be provided inside the base 120. The levitation unit cells 131 may suck or eject gas through the internal space of the base 120.

The conveyance unit 11 illustrated in FIG. 1 conveys the substrate 100 being levitated in a conveyance direction. The conveyance unit 11 includes a holding mechanism 12 and a moving mechanism 13. The holding mechanism 12 holds the substrate 100. For example, the holding mechanism 12 may be constructed by using a vacuum adsorption mechanism. The vacuum adsorption mechanism is formed of a metallic material such as aluminum alloy. Alternatively, the holding mechanism 12 may be formed of a resin material such as a polyetheretherketone (PEEK) material. Adsorption grooves, adsorption holes, or the like are formed at the upper surface of the holding mechanism 12. The holding mechanism 12 may be formed of a porous material.

The holding mechanism 12 (vacuum adsorption mechanism) is connected to an exhaust port (not illustrated), and the exhaust port is connected to an ejector, a vacuum pump, or the like. Accordingly, negative pressure for sucking gas acts on the holding mechanism 12, and thus the substrate 100 can be held by using the holding mechanism 12.

The holding mechanism 12 includes an upward-downward movement mechanism (not illustrated) for performing adsorption operation. The upward-downward movement mechanism includes, for example, an actuator such as an air cylinder or a motor. For example, the holding mechanism 12 adsorbs the substrate 100 in a state in which the holding mechanism 12 moves up to an adsorption position. The holding mechanism 12 moves down to a standby position in a state in which adsorption is canceled.

The holding mechanism 12 holds the substrate 100 by sucking a surface (lower surface) of the substrate 100 on a side opposite a surface (upper surface) irradiated with the laser beam 15, in other words, a surface of the substrate 100 on a side facing the levitation unit 10. In FIG. 1, the holding mechanism 12 holds an end part of the substrate 100 in the +y direction.

The moving mechanism 13 included in the conveyance unit 11 is coupled to the holding mechanism 12. The moving mechanism 13 is configured to be able to move the holding mechanism 12 in the conveyance direction. The conveyance unit 11 (the holding mechanism 12 and the moving mechanism 13) is provided on an end part side of the levitation unit 10 in the +y direction, and the substrate 100 is conveyed as the moving mechanism 13 moves in the conveyance direction while the substrate 100 is held by the holding mechanism 12.

As illustrated in FIG. 1, for example, the moving mechanism 13 is configured to slide in the conveyance direction at the end part of the levitation unit 10 in the +y direction. The substrate 100 is conveyed in the conveyance direction as the moving mechanism 13 slides the end part of the levitation unit 10 in the conveyance direction. The conveyance direction is a direction tilted from the x direction. For example, θ is larger than 0° where θ is the angle between the x direction and the conveyance direction.

Accordingly, the levitation unit 10 has a trapezoid shape having four sides when viewed from top. Specifically, the levitation unit 10 has two sides parallel to the y direction of the levitation unit 10, one side parallel to the x direction, and one side (also referred to as a tilted side 10e) tilted from the x direction. The angle θ may be 0°. In other words, the conveyance direction may be parallel to the X direction. In this case, the levitation unit 10 has a rectangular planar shape.

The conveyance speed of the substrate 100 can be controlled by controlling the moving speed of the moving mechanism 13. The moving mechanism 13 includes, for example, a non-illustrated actuator such as a motor, a linear guide mechanism, and an air bearing.

The substrate 100 is irradiated with the laser beam 15. The irradiation region 15a of the laser beam 15 on the substrate 100 is linear with the y direction as the longitudinal direction. Accordingly, the irradiation region 15a has a longitudinal direction (line direction) along the y direction and has a transverse direction along the x direction.

For example, the laser irradiation unit 14 includes an excimer laser beam source or the like that generates the laser beam. The laser irradiation unit 14 additionally includes an optical system that guides the laser beam to the substrate 100. The laser irradiation unit 14 includes a lens that focuses the laser beam 15 onto the substrate 100. For example, the laser irradiation unit 14 includes a cylindrical lens for forming the linear irradiation region 15a. The substrate 100 is irradiated with the laser beam 15 (line beam) that is linear, and specifically, has a focal point extending in the y direction. The focal point of the laser beam 15 is formed on the substrate 100. Thus, high accuracy is requested for the amount of levitation in the precise levitation region 31 to reduce in-plane variance.

The substrate 100 is, for example, a glass substrate on which an amorphous film (amorphous silicon film 101a) is formed. The amorphous film can be crystallized by irradiating the amorphous film with the laser beam 15 and annealing. For example, the amorphous silicon film 101a can be converted into a polycrystalline silicon film (poly-silicon film 101b).

In the laser irradiation apparatus 1, while the substrate 100 is levitated by using the levitation unit 10, the lower surface of the substrate 100 is held by using the conveyance unit 11 and the substrate 100 is conveyed in the conveyance direction. The conveyance unit 11 included in the laser irradiation apparatus 1 conveys the substrate 100 while holding a position where the conveyance unit 11 dose not overlap the irradiation region 15a in a plan view (when viewed in the z direction) when the substrate 100 is conveyed. In other words, as illustrated in FIG. 1, a position (corresponding to the position of the holding mechanism 12) where the conveyance unit 11 holds the substrate 100 does not overlap the irradiation region 15a when the substrate 100 is conveyed in the conveyance direction.

For example, the substrate 100 has a rectangular (quadrilateral) planar shape having four sides, and the conveyance unit 11 (holding mechanism 12) holds only one of the four sides of the substrate 100. The conveyance unit 11 (holding mechanism 12) holds a position not irradiated with the laser beam in a duration in which the substrate 100 is conveyed.

With such a configuration, the position (corresponding to the position of the holding mechanism 12) where the conveyance unit 11 holds the substrate 100 and the irradiation region 15a can be separated from each other. The irradiation region 15a is substantially half of the −y side of the substrate 100, and the conveyance unit 11 holds its end part on the +y side. The distance between a place where deflection is large in the vicinity of the holding mechanism 12 and the irradiation region 15a can be increased. Thus, influence on the substrate 100 from deflection attributable to the holding mechanism 12 at laser irradiation can be reduced.

The length of the irradiation region 15a in the y direction is a length substantially half of the substrate 100. Accordingly, the amorphous silicon film 101a is crystallized in a substantially half region of the substrate 100 when the substrate 100 passes through the irradiation region 15a once. After the substrate 100 is rotated by 180° about the z axis by a non-illustrated rotary mechanism, the conveyance unit 11 conveys the substrate 100 in the −x direction. Alternatively, the substrate 100 rotated may be conveyed in the −x direction and then may be conveyed in the +x direction again by the conveyance unit 11. The substrate 100 is irradiated with the laser beam during conveyance in the -x direction or conveyance in the +x direction again after rotation by 180°. Accordingly, the substrate 100 passes through the irradiation region 15a, and the amorphous silicon film 101a is crystallized in the remaining half region of the substrate 100. In this manner, the amorphous silicon film 101a is converted into the poly-silicon film 101b on substantially the entire substrate 100 as the substrate 100 is reciprocated.

The conveyance direction is tilted from the x direction orthogonal to the linear irradiation region 15a. In other words, the substrate 100 is conveyed in the conveyance direction tilted from an end side of the substrate 100 in a quadrilateral shape. Substrate conveyance suitable for a laser irradiation process can be achieved when the conveyance direction is a direction tilted from the x direction when viewed from top. Thus, a silicon film crystallization process can be appropriately performed and display quality can be improved. With this configuration, for example, moire generation can be prevented.

For example, the substrate 100 is a glass substrate for an organic light-emitting diode display apparatus. In a case where the organic light-emitting diode display apparatus has a quadrilateral display region, end sides of the display region are disposed in parallel to end sides of the substrate 100. Accordingly, organic light-emitting diode display apparatus includes a quadrilateral display region having short sides in the x direction and the y direction. In a case where the conveyance direction is parallel to the x direction, the substrate 100 is irradiated with the laser beam in a state in which a pixel array direction and the irradiation region 15a are parallel to each other.

As described in the present embodiment, a laser irradiation process can be appropriately performed when the conveyance direction is a direction tilted from the x direction. The moving mechanism 13 moves the holding mechanism 12 in the conveyance direction tilted from the x direction orthogonal to the longitudinal direction of the linear irradiation region 15a when viewed from top to change a laser irradiation position on the substrate 100. Thus, a silicon film crystallization process can be appropriately performed. For example, moire generation can be prevented and display quality can be improved.

### Orbiting Conveyance

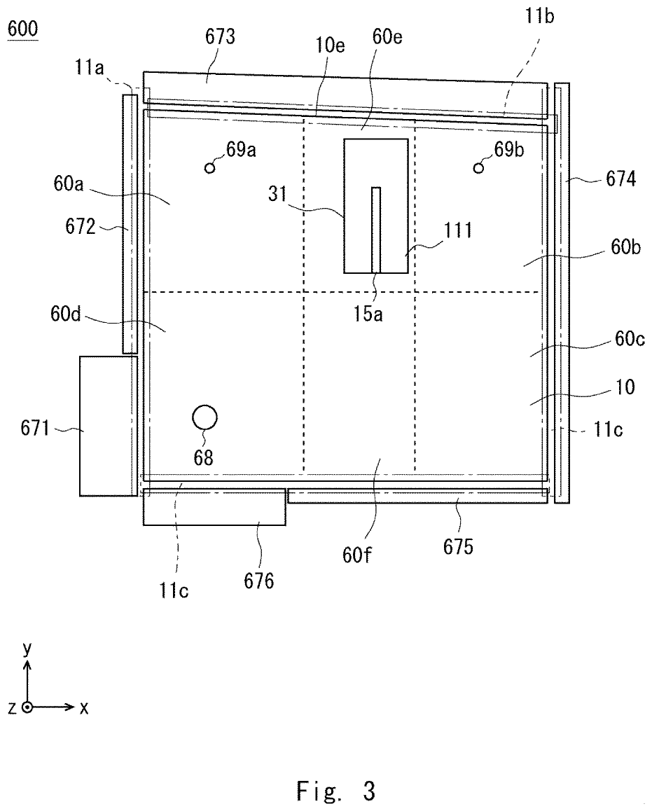

The configuration of the conveyance apparatus 600 will be described next with reference to FIG. 3. FIG. 3 is a top view illustrating the configuration of the conveyance apparatus 600. Note that description of the same contents as contents of the above description with reference to FIGS. 1 and 2 is omitted as appropriate. A nozzle unit 140, a pusher pin 701, and a pusher bar 751 to be described later are omitted from the conveyance apparatus 600. Note that the nozzle unit 140, the pusher pin 701, and the pusher bar 751 can be omitted as appropriate.

The conveyance apparatus 600 includes the levitation unit 10 and end part levitation units 671 to 676. The levitation unit 10 levitates a substrate (not illustrated in FIG. 3) that is a processing target body. The levitation unit 10 has a trapezoid shape when viewed from top. The levitation unit 10 has two sides parallel to the y direction, one side parallel to the x direction, and one side (also referred to as the tilted side 10e) tilted from the x direction. The angle between the tilted side 10e and the x direction is preferably larger than 0°. The end part levitation units 671 to 676 levitate substrate end parts protruding from the levitation unit 10.

Hereinafter, the levitation unit 10 is divided into six regions 60a to 60f when viewed from top for purpose of description. Specifically, the levitation unit 10 includes the first region 60a to the fourth region 60d, a process region 60e, and a passing region 60f. The first region 60a is a trapezoid region including a corner (upper-left corner in FIG. 3) on the −x side and the +y side. The second region 60b is a trapezoid region including a corner (upper-right corner in FIG. 3) on the +x side and the +y side. The third region 60c is a quadrilateral region including a corner (lower-right corner in FIG. 3) on the +x side and the −y side. The fourth region 60d is a quadrilateral region including a corner (lower-left corner in FIG. 3) on the −x side and the −y side.

The process region 60e is a trapezoid region disposed between the first region 60a and the second region 60b. The process region 60e is a region including the irradiation region 15a to be irradiated with the laser beam. The passing region 60f is a quadrilateral region disposed between the third region 60c and the fourth region 60d.

The half region (upper half region in FIG. 3) of the levitation unit 10 on the +y side is the first region 60a, the process region 60e, and the second region 60b in order from the −x side (left side in FIG. 3). The half region (lower half region in FIG. 3) of the levitation unit 10 on the −y side is the third region 60c, the passing region 60f, and the fourth region 60d in order from the +x side.

The fourth region 60d is a loading region where the substrate 100 is loaded, and an unloading region where the substrate 100 is unloaded. For example, a transfer machine (not illustrated) such as a transfer robot is provided on the −x side of the fourth region 60d. The transfer machine loads the substrate 100 into the fourth region 60d. Similarly, the transfer machine unloads the substrate in the fourth region 60d. A pusher pin to be described later may be used for loading and unloading of the substrate 100. In a case where a configuration in which the pusher pin is not used is employed, a rotary mechanism 68 may hand over the substrate 100 in place of the pusher pin.

The levitation unit 10 includes the rotary mechanism 68 and alignment mechanisms 69a and 69b. The rotary mechanism 68 rotates the substrate. The alignment mechanisms 69a and 69b align the substrate. The alignment mechanisms 69a and 69b are provided in the first region 60a and the second region 60b, respectively. The rotary mechanism 68 is provided in the fourth region 60d. Operation of the rotary mechanism 68, the alignment mechanisms 69a and 69b, and the like will be described later.

The end part levitation units 671 to 676 are disposed outside the levitation unit 10. The end part levitation units 671 to 676 are disposed along the outer periphery of the levitation unit 10 in a trapezoid shape. The end part levitation units 671 to 676 are provided along end sides of the levitation unit 10. The end part levitation units 671 to 676 are disposed to surround the outer periphery of the levitation unit 10 when viewed from top.

The end part levitation units 671 and 672 are disposed on the −x side of the levitation unit 10. The end part levitation unit 673 is disposed on the +y side of the levitation unit 10. The end part levitation unit 674 is disposed on the +x side of the levitation unit 10. The end part levitation units 675 and 676 are disposed on the −y side of the levitation unit 10.

The end part levitation units 671 and 672 are disposed along an end side of the levitation unit 10 on the −x side. Accordingly, the end part levitation units 671 and 672 are each provided in the y direction. The width of the end part levitation unit 671 in the x direction is wider than that of the end part levitation unit 672. The end part levitation unit 671 is disposed on the −y side of the end part levitation unit 672.

The end part levitation unit 673 is disposed along an end side of the levitation unit 10 on the +y side. Accordingly, the end part levitation unit 673 is provided along the tilted side 10e of the levitation unit 10. The end part levitation unit 674 is disposed along an end side of the levitation unit 10 on the +x side. Accordingly, the end part levitation unit 674 is provided in the y direction.

The end part levitation units 675 and 676 are disposed along an end side of the levitation unit 10 on the −y side. Accordingly, the end part levitation units 675 and 676 are each provided in the x direction. The width of the end part levitation unit 676 in the y direction is wider than that of the end part levitation unit 675. The end part levitation unit 676 is disposed on the −x side of the end part levitation unit 675.

A conveyance unit 11a is provided between the levitation unit 10 and the end part levitation unit 671. The conveyance unit 11a is also disposed between the levitation unit 10 and the end part levitation unit 672. The conveyance unit 11a is formed in the y direction. The conveyance unit 11a conveys the substrate in the +y direction. Specifically, the conveyance unit 11a conveys the substrate 100 from the fourth region 60d toward the first region 60a.

A conveyance unit 11b is provided between the levitation unit 10 and the end part levitation unit 673. The conveyance unit 11b is formed along the tilted side 10e. The conveyance unit 11b conveys the substrate in a direction parallel to the tilted side 10e. Specifically, the conveyance unit 11b conveys the substrate 100 from the first region 60a toward the second region 60b.

A conveyance unit 11c is provided between the levitation unit 10 and the end part levitation unit 674. The conveyance unit 11c is formed in the y direction. The conveyance unit 11c conveys the substrate 100 in the −y direction. Specifically, the conveyance unit 11c conveys the substrate 100 from the second region 60b toward the third region 60c.

A conveyance unit 11d is provided between the levitation unit 10 and the end part levitation unit 675. The conveyance unit 11d is also disposed between the levitation unit 10 and the end part levitation unit 676. The conveyance unit 11d is formed in the x direction. The conveyance unit 11a conveys the substrate in the −x direction. Specifically, the conveyance unit 11d conveys the substrate from the third region 60c toward the fourth region 60d.

Note that the conveyance units 11a to 11d each include the holding mechanism 12 and the moving mechanism 13 illustrated in FIG. 1. Operation of the holding mechanism 12 and the moving mechanism 13 will be described later.

The irradiation region 15a of the laser beam has a longitudinal direction in the y direction. In other words, the linear irradiation region 15a having a longitudinal direction in the y direction is formed. The substrate 100 is irradiated with the laser beam while the substrate 100 is conveyed in the direction parallel to the tilted side 10e. A laser irradiation process is executed while the substrate 100 is moved from the first region 60a to the second region 60b. In the present embodiment as well, an amorphous silicon film is converted into a poly-silicon film by irradiating a substrate with a laser beam from a laser beam source.

Note that, in the levitation unit 10, the precise levitation units 111 are disposed in and around the irradiation region 15a. The precise levitation units 111 have a higher accuracy of levitation amount than the semi-precise levitation units and the rough levitation units in the other region. Thus, the substrate 100 being levitated with the amount of levitation at higher accuracy is irradiated with the laser beam in the process region 60e including the irradiation region 15a than in the other regions 60a to 60d and 60f. Accordingly, the substrate 100 can be stably irradiated with the laser beam. The other regions than the irradiation region 15a, for example, the passing region 60f, the third region 60c, and the fourth region 60d are produced without using the precise levitation units 111 that are expensive. Thus, apparatus cost can be reduced.

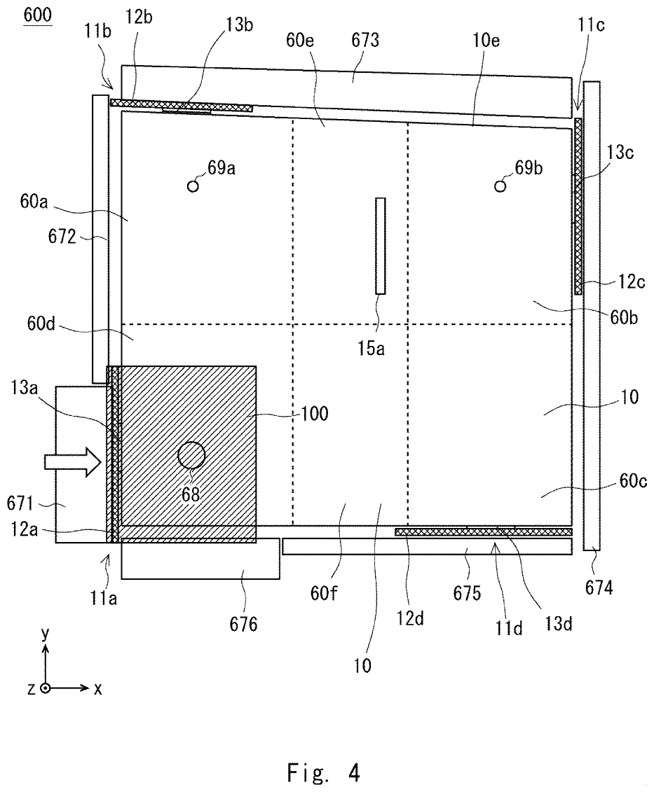

The procedure of a conveyance method using the levitation unit 10 will be described next with reference to FIGS. 4 to 11. In this example, the fourth region 60d is the loading position and unloading position of the substrate 100. The substrate 100 loaded into the fourth region 60d is conveyed through the first region 60a, the process region 60e, the second region 60b, the third region 60c, the passing region 60f, and the fourth region 60d in the stated order. Accordingly, the substrate 100 orbits along the end sides of the levitation unit 10. The substrate 100 orbits twice to irradiate the entire substrate 100 with the laser beam. In other words, the substrate 100 is conveyed to circulate twice over the levitation unit 10. In this manner, substantially the entire surface of the substrate 100 is irradiated with the laser beam.

The following description is performed in detail along the procedure of the conveyance method. As illustrated in FIG. 4, the substrate 100 is loaded into the fourth region 60d. The substrate 100 loaded into the fourth region 60d is levitated by the levitation unit 10 and the end part levitation units 671, 672, and 676. Specifically, the end part of the substrate 100 on the −x side is levitated by the end part levitation units 671 and 672, and a central part thereof is levitated by the levitation unit 10. The end part of the substrate 100 on the −y side is levitated by the end part levitation unit 676. A holding mechanism 12a of the conveyance unit 11a holds the substrate 100.

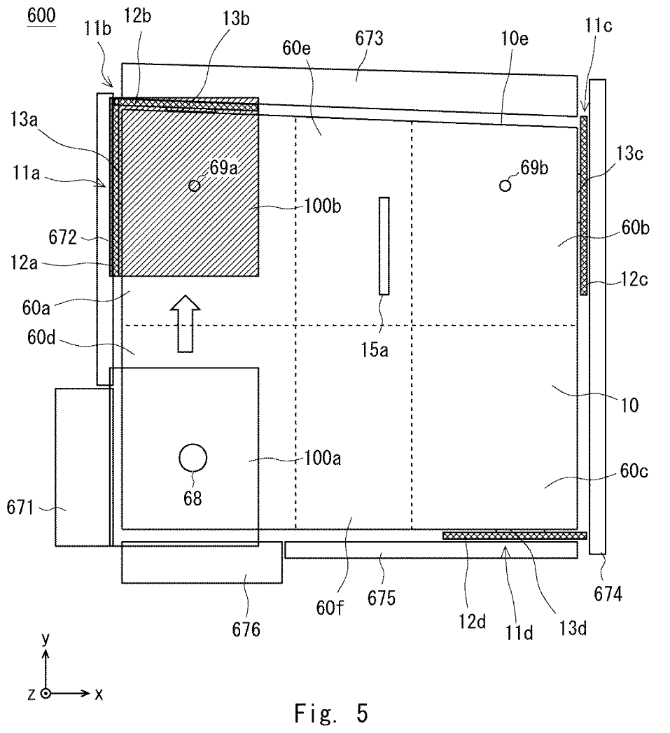

Subsequently, as illustrated in FIG. 5, a substrate 100a in the fourth region 60d is conveyed to the first region 60a. In FIG. 5, the substrate having moved to the first region 60a is illustrated as a substrate 100b. The holding mechanism 12a of the conveyance unit 11a holds the substrate 100a. Then, the substrate 100a is moved from the fourth region 60d to the first region 60a (white arrow in FIG. 5) as a moving mechanism 13a moves the holding mechanism 12a in the +y direction.

The holding mechanism 12a passes between the levitation unit 10 and the end part levitation unit 671 in an xy plan view and moves in the +y direction. In addition, the holding mechanism 12a passes between the levitation unit 10 and the end part levitation unit 672 in an xy plan view and moves in the +y direction. Accordingly, the substrate 100b is levitated by the levitation unit 10 and the end part levitation units 672 and 673. Specifically, the end part of the substrate 100b on the −x side is levitated by the end part levitation unit 672, and a central part thereof is levitated by the levitation unit 10. The end part of the substrate 100b on the +y side is levitated by the end part levitation unit 673.

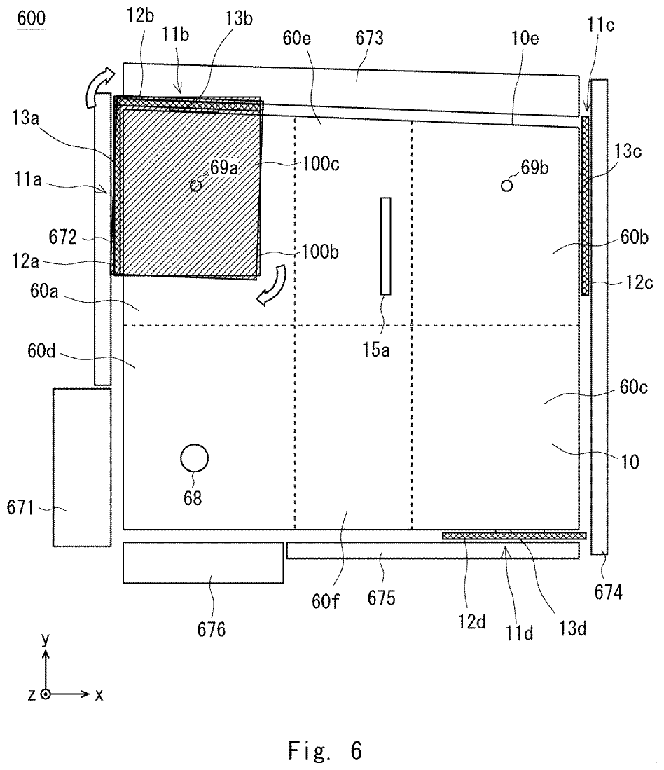

Subsequently, as illustrated in FIG. 6, the alignment mechanism 69a aligns the position and angle of the substrate 100b conveyed to the first region 60a. The position and rotation angle of the substrate 100 are slightly shifted due to, for example, loading operation, conveyance operation, and rotation operation of the substrate in some cases. The alignment mechanism 69a corrects shift in the position and the rotation angle. Accordingly, the irradiation position of the laser beam on the substrate 100 can be accurately controlled.

For example, the alignment mechanism 69a is movable in the y direction and rotatable about the z axis. In addition, the alignment mechanism 69a is movable in the z direction. For example, the alignment mechanism 69a includes an actuator such as a motor. The amount of positional shift and the amount of angle shift are determined based on an image of the substrate 100b captured by a camera or the like. The alignment mechanism 69a performs alignment based on the shift amounts.

The alignment mechanism 69a is disposed directly below the central part of the substrate 100b. The alignment mechanism 69a holds the substrate 100b. Similarly to the holding mechanism 12, the alignment mechanism 69a may hold the substrate 100b by adsorption. The holding mechanism 12a releases holding of the substrate 100b. Accordingly, the substrate 100b is handed over from the holding mechanism 12a to the alignment mechanism 69a.

Then, the alignment mechanism 69a rotates the substrate 100b about the z axis (white arrow in FIG. 6). The alignment mechanism 69a rotates the substrate 100b so that an end side of the substrate 100b becomes parallel to the tilted side 10e of the levitation unit 10. The substrate after the rotation is illustrated as a substrate 100c. For example, the alignment mechanism 69a rotates the substrate 100 by a predetermined angle about the z axis. An end side of the substrate 100c is parallel to the tilted side 10e of the levitation unit 10. After the alignment ends, a holding mechanism 12b of the conveyance unit 11b holds the substrate 100b, and the alignment mechanism 69a releases the holding. Accordingly, the substrate 100c is handed over from the alignment mechanism 69a to the holding mechanism 12b of the conveyance unit 11b.

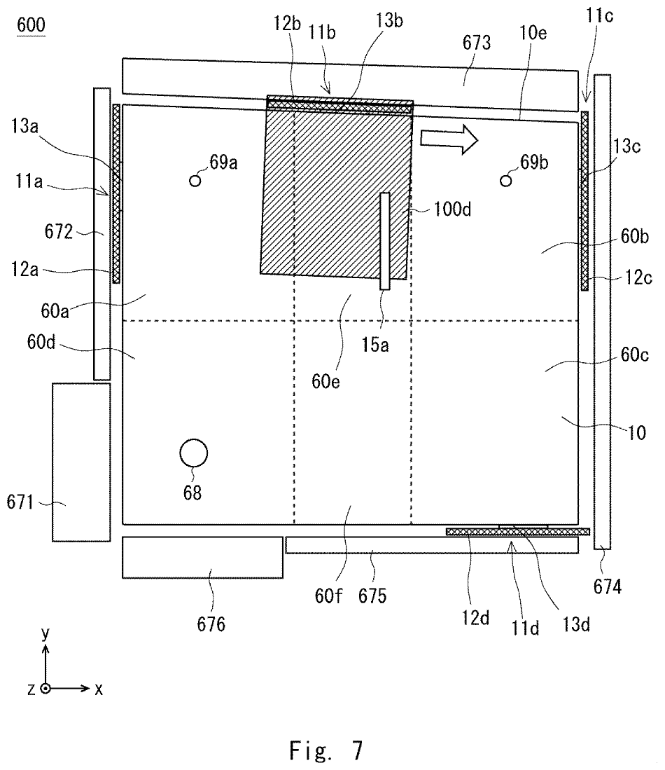

Subsequently, as illustrated in FIG. 7, the conveyance unit 11b moves a substrate 100d. Accordingly, the substrate 100d passes through the process region 60e. The holding mechanism 12b passes between the levitation unit 10 and the end part levitation unit 673 in an xy plan view and moves in the direction parallel to the tilted side 10e. Accordingly, a substantially half region of the substrate 100d passes through the irradiation region 15a. The substrate 100d moving in a tilt direction tilted from the x direction orthogonal to the irradiation region 15a is irradiated with the laser beam.

The holding mechanism 12b passes between the levitation unit 10 and the end part levitation unit 673 in an xy plan view and moves in the direction parallel to the tilted side 10e. Accordingly, the substrate 100d is levitated by the levitation unit 10 and the end part levitation unit 673. Specifically, an end part of the substrate 100d on the +y side is levitated by the end part levitation unit 673, and a central part thereof is levitated by the levitation unit 10. A laser irradiation process is performed while the substrate 100d is moved from the first region 60a to the second region 60b.

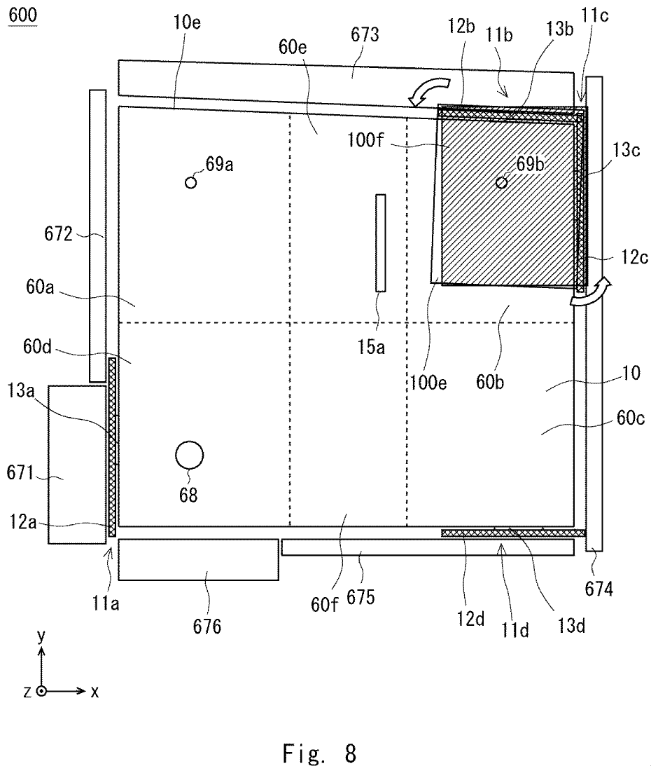

Subsequently, as illustrated in FIG. 8, the alignment mechanism 69b aligns a substrate 100e after the substrate 100e is moved to the second region 60b. Specifically, the alignment mechanism 69b rotates the substrate 100e (white arrow in FIG. 8). In FIG. 8, the substrate after rotation is illustrated as a substrate 100f.

The alignment mechanism 69b is disposed directly below a central part of the substrate 100e. The alignment mechanism 69b holds the substrate 100e. Similarly to the holding mechanism 12, the alignment mechanism 69b may hold the substrate 100e by adsorption. Further, the holding mechanism 12b releases holding of the substrate 100e. The substrate 100e is handed over from the holding mechanism 12b of the conveyance unit 11b to the alignment mechanism 69b.

The alignment mechanism 69b rotates the substrate 100e about the z axis (white arrow in FIG. 8). The alignment mechanism 69a rotates the substrate 100e so that an end side of the substrate 100e becomes parallel to the tilted side 10e of the levitation unit 10. The end side of the substrate 100f after the rotation is parallel to the x direction or the y direction. After the alignment ends, a holding mechanism 12c of the conveyance unit 11c holds the substrate 100f, and the alignment mechanism 69b releases the holding. Accordingly, the substrate 100f is handed over from the alignment mechanism 69b to the holding mechanism 12c of the conveyance unit 11c.

The substrate 100e is levitated by the levitation unit 10 and the end part levitation units 673 and 674. Specifically, an end part of the substrate 100e on the +y side is levitated by the end part levitation unit 673. An end part of the substrate 100e on the +x side is levitated by the end part levitation unit 674, and a central part thereof is levitated by the levitation unit 10.

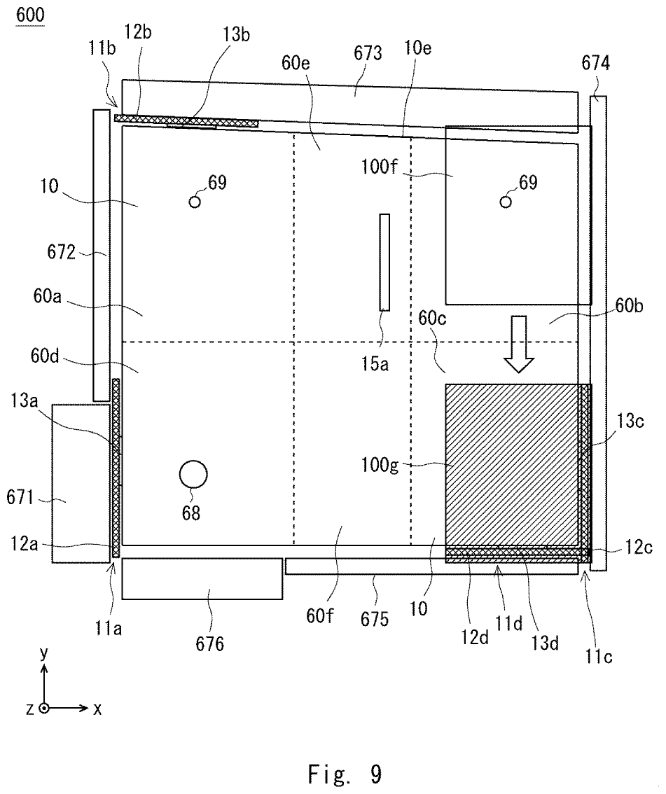

Subsequently, as illustrated in FIG. 9, the substrate 100f in the second region 60b is conveyed to the third region 60c. The substrate having moved to the third region 60c is illustrated as a substrate 100g. In FIG. 9, the holding mechanism 12c of the conveyance unit 11c holds the substrate 100f. Then, the substrate 100f is moved from the second region 60b to the third region 60c (white arrow in FIG. 9) as a moving mechanism 13c moves the holding mechanism 12c in the −y direction.

The holding mechanism 12c passes between the levitation unit 10 and the end part levitation unit 674 in an xy plan view and moves in the −y direction. Accordingly, the substrate 100e is levitated by the levitation unit 10 and the end part levitation units 674 and 675. The end part of the substrate 100e on the +x side is levitated by the end part levitation unit 674, and the central part thereof is levitated by the levitation unit 10. An end part of the substrate 100e on the −y side is levitated by the end part levitation unit 675.

Then, a holding mechanism 12d of the conveyance unit 11d holds the substrate 100g, and the holding mechanism 12c releases the holding. Accordingly, the substrate 100g is handed over from the holding mechanism 12c of the conveyance unit 11c to the holding mechanism 12d of the conveyance unit 11d.

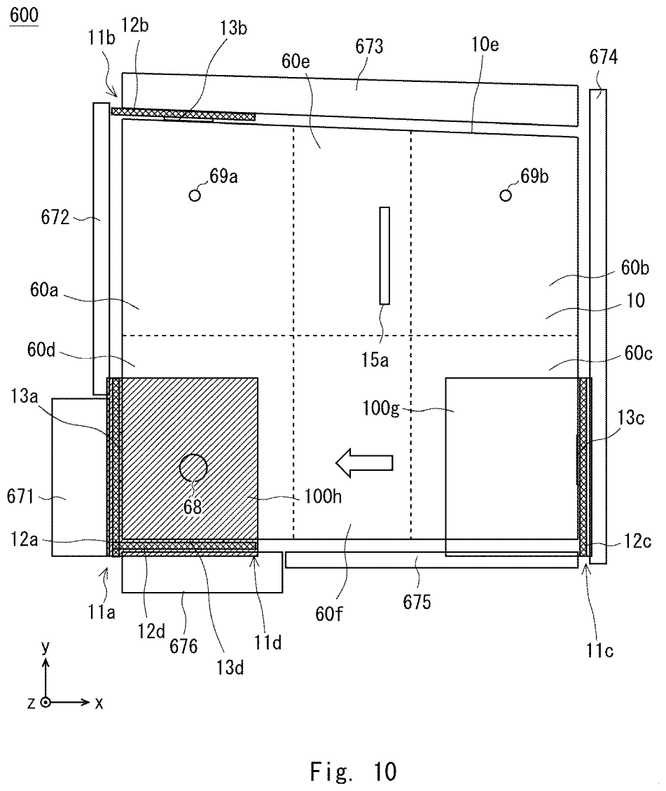

Subsequently, as illustrated in FIG. 10, the substrate 100g in the third region 60c is conveyed to the fourth region 60d. The substrate having moved to the fourth region 60d is illustrated as a substrate 100h. In FIG. 10, the holding mechanism 12d of the conveyance unit 11d holds the substrate 100g. Then, the substrate 100f is moved from the third region 60c to the fourth region 60d (white arrow in FIG. 10) as a moving mechanism 13d moves the holding mechanism 12d in the −x direction.

The holding mechanism 12d passes between the levitation unit 10 and the end part levitation unit 675 in an xy plan view and moves in the −x direction. The holding mechanism 12d passes between the levitation unit 10 and the end part levitation unit 676 in an xy plan view and moves in the −x direction. Accordingly, the substrate 100h is levitated by the levitation unit 10 and the end part levitation unit 676. An end part of the substrate 100h on the −y side is levitated by the end part levitation unit 676, and a central part thereof is levitated by the levitation unit 10. An end part of the substrate 100h on the −x side is levitated by the end part levitation unit 671.

In this manner, the substrate 100 in the fourth region 60d moves through the first region 60a, the process region 60e, the second region 60b, the third region 60c, the passing region 60f, and the fourth region 60d in the stated order. In other words, the substrate 100 orbits along the end sides of the levitation unit 10.

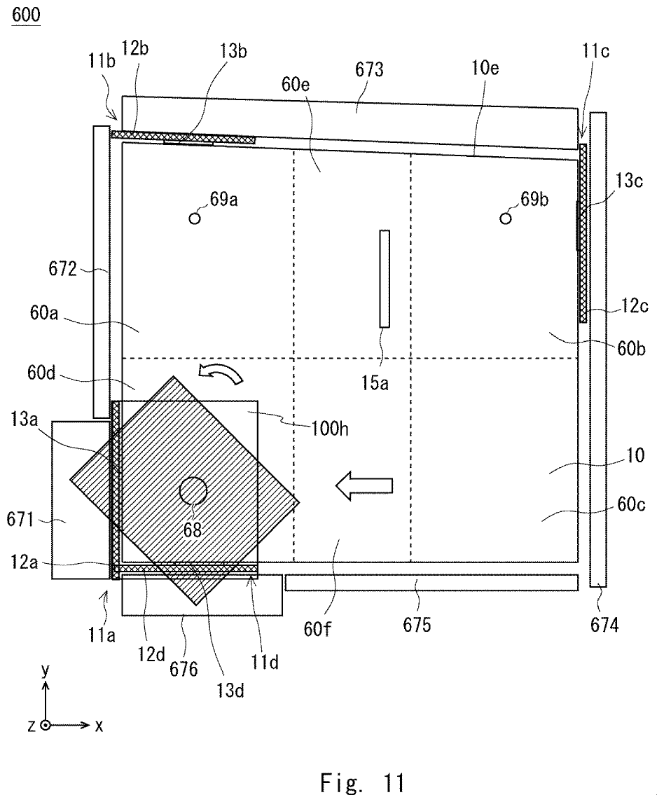

Subsequently, as illustrated in FIG. 11, the rotary mechanism 68 rotates the substrate 100h by 180° about the z axis. Accordingly, the substrate 100h is handed over from the holding mechanism 12d to the rotary mechanism 68. After the rotary mechanism 68 rotates the substrate 100h, the substrate 100h is handed over from the rotary mechanism 68 to the holding mechanism 12d.

In the same manner as described above, the conveyance units 11a to 11d moves the substrate 100h again through the first region 60a, the process region 60e, the second region 60b, the third region 60c, the passing region 60f, and the fourth region 60d in the stated order. In other words, the substrate 100 orbits along the end sides of the levitation unit 10 as illustrated in FIGS. 4 to 11.

The rotary mechanism 68 rotates the substrate 100h by 180°. As the substrate 100e passes through the process region 60e for the second time, the remaining half region not irradiated with the laser beam through the first passing is irradiated with the laser beam. In this manner, the substrate 100 circulates twice along the end sides of the levitation unit 10. Since the substrate 100 is rotated by 180° between the first laser irradiation and the second laser irradiation, substantially the entire surface of the substrate 100 is irradiated with the laser beam. Note that a position where the substrate 100 is rotated is not limited to the first region 60a. For example, the rotation may be performed in the second region 60b, the third region 60c, or the fourth region 60d.

In the present embodiment as well, a moving mechanism 13b conveys the holding mechanism 12b in a direction tilted from the x direction orthogonal to the irradiation region 15a. Thus, a silicon film crystallization process can be appropriately performed. For example, moire generation can be prevented and display quality can be improved. The conveyance direction of the substrate 100 may be the X direction. The conveyance direction of the substrate 100 only needs to be a direction tilted from the Y direction when viewed from top. Specifically, the conveyance direction of the substrate may be parallel to the X direction or may be a direction tilted from the X direction.

### Nozzle Unit

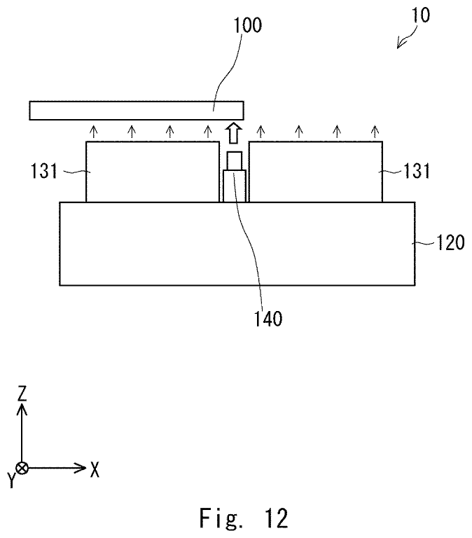

A nozzle unit may be provided at the conveyance apparatus 600. The nozzle unit provided at the conveyance apparatus 600 will be described below. FIG. 12 is a side cross-sectional view schematically illustrating the configuration of the levitation unit 10. Components other than the levitation unit 10 and its surroundings are omitted in FIG. 12. The levitation unit 10 includes the base 120, the levitation unit cells 131, and the nozzle unit 140.

The levitation unit 10 includes a plurality of levitation unit cells 131. As described above, each levitation unit cell 131 is a precise levitation unit 111, a semi-precise levitation unit 112, or a rough levitation unit 113. The plurality of levitation unit cells 131 are fixed to the base 120. FIG. 2 is a simplified diagram and thus illustrates only two levitation unit cells 131, but a large number of levitation unit cells 131 are arrayed in the X direction and the Y direction over the entire levitation unit 10.

One levitation unit cell 131 is formed as one porous body block or metal block. Each levitation unit cell 131 is formed in, for example, a quadrilateral shape or a trapezoid shape when viewed from top. The levitation unit cells 131 are arrayed, for example, in the X direction or the Y direction. The upper surface of each levitation unit cell 131 serves as a gas ejection surface.

The plurality of levitation unit cells 131 are fixed on the base 120. The base 120 is formed of a metallic material such as aluminum alloy. The levitation unit cells 131 are attached to the upper surface of the base 120 by bolts or the like. Note that flatness of the upper surface of the base 120 is preferably increased to control the amount of levitation of the substrate 100 at high accuracy. The upper surface of the base 120 may be polished. Accordingly, the upper surfaces of the plurality of levitation unit cells 131 can have uniform heights.

The nozzle unit 140 is provided in a gap 132 between two adjacent levitation unit cells 131. In other words, the gap 132 having a width larger than that of the nozzle unit 140 is provided between two adjacent levitation unit cells 131. The nozzle unit 140 is disposed in the gap 132. The gap 132 is, for example, a groove having a predetermined width. The nozzle unit 140 is disposed along the gap 132. The nozzle unit 140 is disposed on the lower side of the substrate 100 and ejects compressed gas toward the lower surface of the substrate 100. The nozzle unit 140 ejects gas at ejection speed higher than that of the levitation unit cells 131.

Since the nozzle unit 140 is provided at the levitation unit 10, an end part of the substrate 100 can be prevented from contacting the levitation unit cells 131. For example, the nozzle unit 140 is disposed directly below a place through which an end part or corner of the substrate 100 passes. In this manner, even when the end part or corner of the substrate 100 droops, the end part of the substrate 100 can be prevented from contacting the levitation unit 10. Thus, the substrate 100 can be appropriately conveyed.

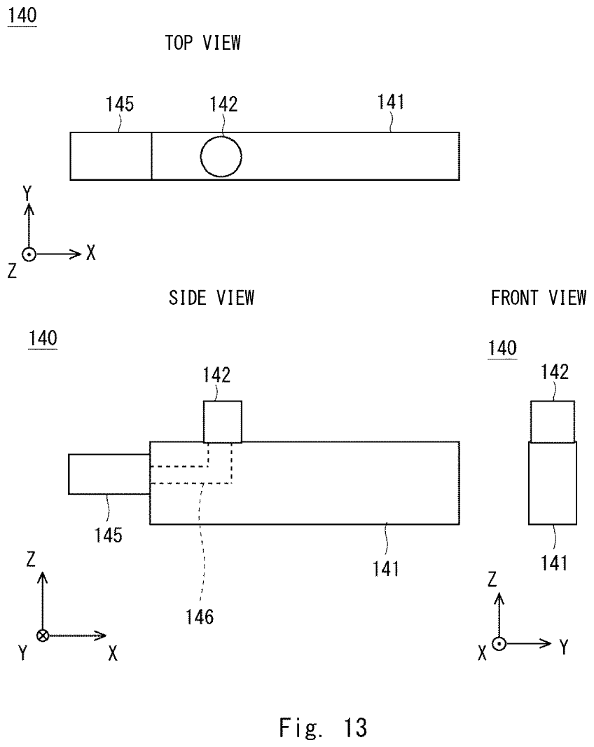

The configuration of the nozzle unit 140 will be described below with reference to FIG. 13. FIG. 13 illustrates a top view, a side view, and a front view of the nozzle unit 140. The nozzle unit 140 includes a body part 141, an ejection part 142, and a connection part 145.

The ejection part 142 is provided at the upper surface of the body part 141. The connection part 145 is provided on a side surface of the body part 141. The body part 141 is fixed to the base 120 by screws, bolts, or the like. The connection part 145 includes a joint and is connected to a gas pipe or the like. The ejection part 142 is provided with an ejection port that ejects gas upward. The ejection part 142 includes a nozzle disposed upward. Accordingly, the gas ejection speed upward can be increased. The gas ejection speed of the nozzle unit 140 may be higher than the gas ejection speed of the levitation unit cells 131. The substrate 100 can be prevented from drooping while being levitated, and the substrate 100 can be prevented from contacting the levitation unit 10.

The body part 141 is a hollow block and has an internal space 146. The ejection part 142 and the connection part 145 are connected to each other through the internal space 146 of the body part 141. Compressed gas such as dry air or dry nitrogen is supplied from a gas pipe connected to the connection part 145. The gas passes through the internal space 146 of the body part 141 and is ejected upward from the ejection part 142. The gas can be ejected toward the lower surface of the substrate 100. The substrate 100 can be prevented from drooping while being levitated, and the substrate 100 can be prevented from contacting the levitation unit 10.

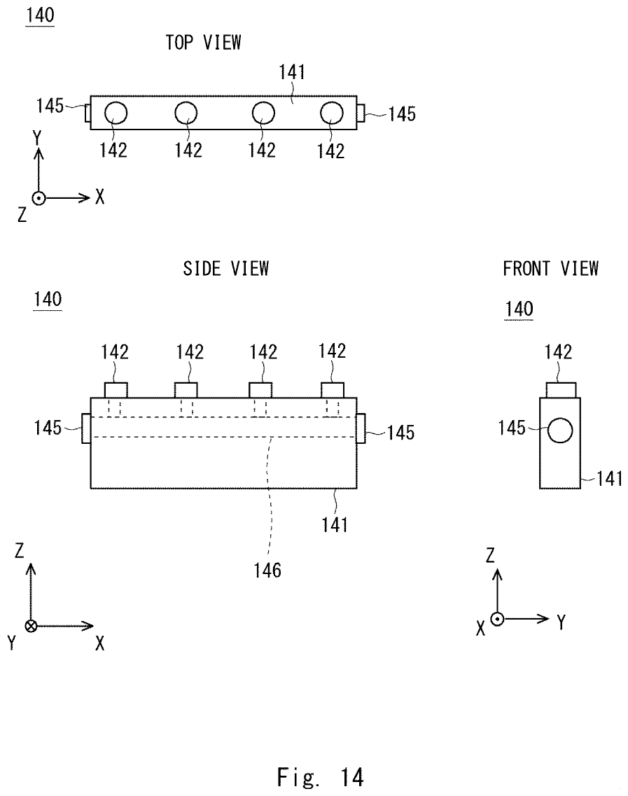

The body part 141 may be a manifold including a plurality of ejection parts 142 as illustrated in FIG. 14. In FIG. 14, four ejection parts 142 are provided at the upper surface of the body part 141. Each ejection part 142 includes a nozzle that ejects gas upward. Accordingly, gas is ejected upward from four places. In this manner, the substrate 100 can be more effectively prevented from drooping while moving.

In FIG. 14, two connection parts 145 are provided at the body part 141. The two connection parts 145 are provided at facing side surfaces of the body part 141. Since the plurality of connection parts 145 are provided, two nozzle units 140 can be connected in series. Specifically, two nozzle units 140 as illustrated in FIG. 14 are arranged such that the corresponding connection parts 145 thereof face each other. The connection part 145 of one of the nozzle units 140 and the connection part 145 of the other nozzle unit 140 are connected to each other through a gas pipe. Accordingly, gas flows from the one nozzle unit 140 to the other nozzle unit 140. In this manner, a plurality of nozzle units 140 can be connected in series. Accordingly, the nozzle units 140 can be disposed at optional positions of the levitation unit 10.

The conveyance method using the conveyance apparatus including the above-described nozzle units 140 includes steps C1 and C2 described below.

(Step C1) step of moving the holding mechanism by the moving mechanism to convey the substrate in the conveyance direction.

(Step C2) step of ejecting, by the nozzle unit, gas to an end part of the substrate being conveyed.

The nozzle units 140 may be locally disposed in the levitation unit 10. Specifically, the nozzle units 140 may be provided only at a place through which an end part or corner of the substrate 100 passes. In addition, the nozzle units 140 may be disposed at a place where the gap 132 increases. Arrangement examples of the nozzle units 140 will be described later.

Gas ejection from the nozzle units 140 may be controlled in accordance with a conveyance position of the substrate 100. Gas supply to the nozzle units 140 may be performed in cooperation with conveyance of the substrate 100. Each nozzle unit 140 may eject gas at the timing when an end part or corner of the substrate 100 is directly above the nozzle unit 140. Thus, each nozzle unit 140 may eject gas or stop ejection at the timing when an end part or corner of the substrate 100 is not directly above the nozzle unit 140. For example, gas ejection can be controlled through on-off control of a valve. Accordingly, gas accumulation can be prevented from occurring, and thus the substrate 100 can be appropriately conveyed.

For example, gas is supplied to each nozzle unit 140 while the substrate 100 passes directly above the nozzle unit 140. Specifically, the nozzle unit 140 ejects gas at the timing when or right before an end part or corner of the substrate 100 passes directly above the nozzle unit 140. In other words, gas supply to the nozzle unit 140 may be stopped in a duration in which the substrate 100 is not directly above the nozzle unit 140. In this manner, the nozzle unit 140 stops gas ejection in accordance with the conveyance position of the substrate 100. For example, while gas is ejected from some of the nozzle units 140, gas ejection from the other nozzle units 140 is stopped.

### Arrangement Example 1 of Nozzle Units

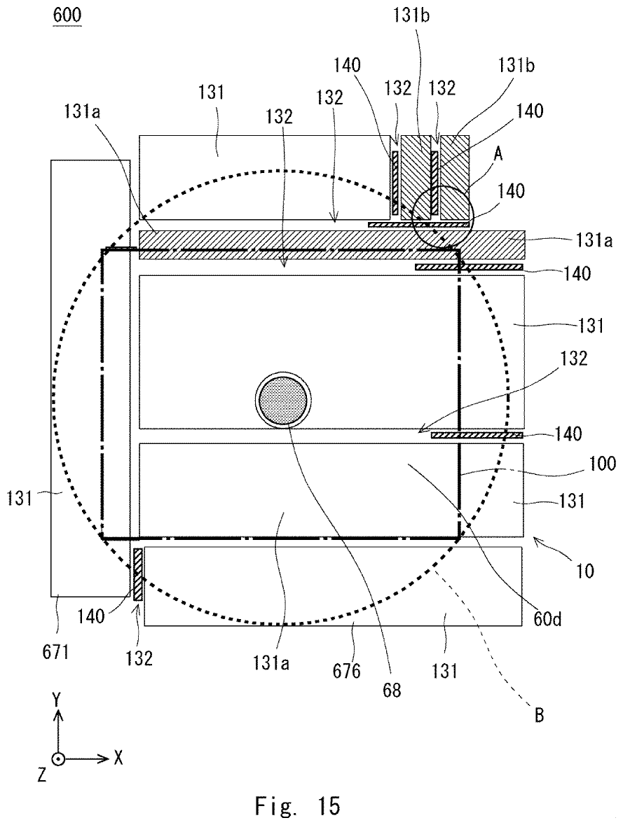

FIG. 15 is a diagram for description of an arrangement example of the nozzle units 140. Specifically, FIG. 15 is a top view illustrating the configuration of the fourth region 60d of the levitation unit 10 and its surroundings. Specifically, the end part levitation unit 671 is provided on the −x side of the levitation unit 10, and the end part levitation unit 676 is provided on the-y side thereof.

A plurality of levitation unit cells 131 are provided in the fourth region 60d. The end part levitation unit 671 includes a plurality of levitation unit cells 131. Similarly, the end part levitation unit 676 includes a plurality of levitation unit cells 131. Each levitation unit cell 131 is formed in a quadrilateral shape in the X direction and the Y direction when viewed from top. Accordingly, each gap 132 is formed in the X direction or the Y direction.

Further, the levitation unit cells 131 are differently oriented in the fourth region 60d. Specifically, levitation unit cells 131 having a longitudinal direction in the X direction and levitation unit cells 131 having a longitudinal direction in the Y direction are provided in the fourth region 60d. In the fourth region 60d, each levitation unit cell 131 in a quadrilateral shape having a longitudinal direction in the X direction is illustrated as a levitation unit cell 131a, and each levitation unit cell 131 in a quadrilateral shape having a longitudinal direction in the Y direction is illustrated as a levitation unit cell 131b.

A nozzle unit 140 is provided at a place A where a levitation unit cell 131a and a levitation unit cell 131b are adjacent to each other. The levitation unit cells 131 are differently oriented at the place A where the levitation unit cell 131a and the levitation unit cell 131b are adjacent to each other. Accordingly, the orientation of substrate levitation behavior changes by 90° at the place A. A corner or end part of the substrate 100 passes through the place A as the substrate 100 is conveyed in the positive Y direction from the fourth region 60d. The amount of levitation tends to decrease as the corner or end part of the substrate 100 passes through the place A. Thus, the nozzle unit 140 is disposed at the place A. Accordingly, the end part of the substrate 100 can be prevented from drooping during conveyance in the positive Y direction.

### Arrangement Example 2 of Nozzle Units 140

As illustrated in FIG. 15, the rotary mechanism 68 may be provided in the fourth region 60d. The rotary mechanism 68 rotates the substrate 100 about a rotational axis parallel to the Z axis. A locus B on which a corner of the substrate 100 passes with rotation of the rotary mechanism 68 is illustrated in FIG. 15. The locus B has a circular shape centered at the rotational axis of the rotary mechanism 68. The nozzle units 140 are disposed on the locus B. Specifically, the nozzle units 140 are disposed directly below the locus B on which a corner of the substrate 100 passes as the substrate 100 is rotated. Accordingly, the end parts of the substrate 100 can be prevented from drooping during rotation of the substrate 100.

In a case where the substrate 100 is rotated, a gas film is difficult to form between the substrate 100 and the levitation unit 10 as compared to a case where the substrate 100 is moved straight. In particular, the amount of levitation of the substrate 100 tends to decrease at the corners and their vicinities. The nozzle units 140 are disposed in gaps 132 over which the corners of the substrate 100 pass during rotation of the substrate 100. Note that the nozzle units 140 are preferably disposed in all or substantially all gaps 132 directly below the locus B of the corners. The nozzle units 140 may be disposed at not all gaps 132 directly below the locus B. For example, no nozzle unit 140 may be provided in a gap 132 at a position that interferes with the conveyance unit 11 directly below the locus B. The nozzle units 140 are preferably disposed so that gas blows onto the corners of the substrate 100 and their surroundings.

### Arrangement Example 3 of Nozzle Units

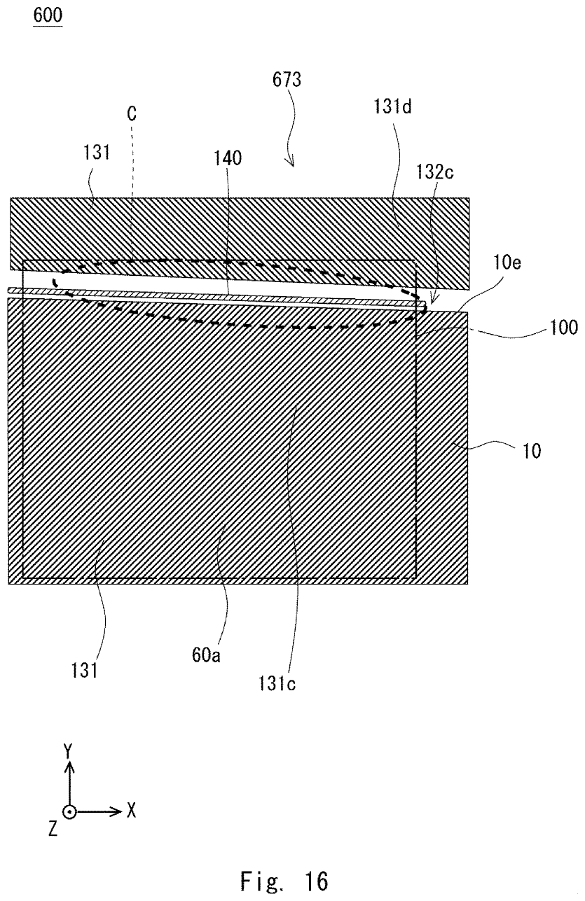

An arrangement example 3 of the nozzle units 140 will be described below with reference to FIG. 16. FIG. 16 is a diagram for description of the arrangement example 3 of a nozzle unit 140. Specifically, FIG. 16 is a top view illustrating the configuration of the first region 60a of the levitation unit 10 and its surroundings. The end part levitation unit 673 is provided on the +y side of the levitation unit 10. In FIG. 16, the nozzle unit 140 is provided at a place C.

A levitation unit cell 131 provided at an end of the first region 60a in the +y side is referred to as a levitation unit cell 131c. The levitation unit cell 131c has a trapezoid shape with one side parallel to the conveyance direction. The levitation unit cell 131 of the end part levitation unit 673 is referred to as a levitation unit cell 131d.

A gap 132c is provided between the levitation unit cell 131c and the levitation unit cell 131d. The gap 132c is parallel to the conveyance direction. Specifically, the gap 132c extends in a direction different from the X direction and the Y direction. The gap 132c is parallel to the tilted side 10e. The conveyance unit 11b moves over the gap 132c. A nozzle unit 140 is provided in the gap 132c. The nozzle unit 140 is disposed to avoid interfere with movement of the conveyance unit 11b.

In a case where the substrate 100 is to be conveyed from the fourth region 60d to the first region 60a, the conveyance unit 11a moves the substrate 100 in the Y direction (refer to FIG. 5). End parts of the substrate 100 move over the gap 132c and reach directly above the levitation unit cell 131d. Since the nozzle unit 140 is disposed in the gap 132c, the end parts of the substrate 100 can be prevented from drooping during conveyance in the positive Y direction.

Note that disposition places of the nozzle units 140 are not limited to the above-described arrangement examples 1 to 3, but the nozzle units 140 may be disposed at any other places. For example, in a case where a gap 132 is wider at a place due to disposition of levitation unit cells, a nozzle unit 140 may be disposed at the place. Moreover, the nozzle units 140 do not necessarily need to be disposed as in one or more of arrangement examples 1 to 3. Further, the nozzle units 140 may be omitted.

### End Part Levitation Unit

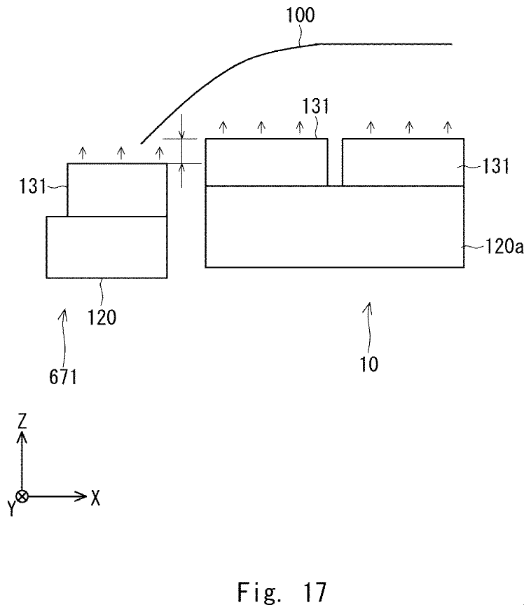

A configuration example of end part levitation units will be described next with reference to FIG. 17. FIG. 17 is a diagram schematically illustrating height difference between the end part levitation unit 671 and the levitation unit 10.

The end parts of the substrate 100 easily droop and become lower than the central part of the substrate 100. Accordingly, in FIG. 17, the upper surface of the levitation unit cell 131 of the end part levitation unit 671 is lower than the upper surfaces of the levitation unit cells 131 of the levitation unit 10. Specifically, the levitation unit cells 131 directly below the end parts of the substrate 100 are disposed lower than the levitation unit cells 131 directly below the central part of the substrate 100. For example, the levitation unit cell 131 of the end part levitation unit 671 is disposed lower than the levitation unit cells 131 of the levitation unit 10. Accordingly, a slight step is provided between the upper surface (ejection surface) of the levitation unit 10 and the upper surface (ejection surface) of the end part levitation unit 671.

With this configuration, the substrate 100 can be prevented from contacting the end part levitation unit 671 even when the end parts of the substrate 100 droop. Note that although only the end part levitation unit 671 is illustrated in FIG. 17, the levitation unit cells 131 of the other end part levitation units 672 to 676 may be lower as well. Moreover, the levitation unit cells 131 of at least one or all of the end part levitation units 671 to 676 may be lower.

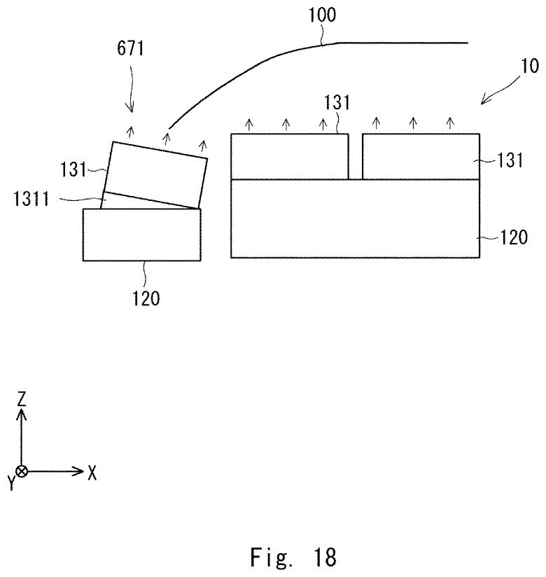

As illustrated in FIG. 18, the levitation unit cell 131 of the end part levitation unit 671 may be obliquely disposed. For example, a height adjustment mechanism 1311 is disposed between the base 120 and the levitation unit cell 131. The height adjustment mechanism 1311 has, for example, a wedge shape and is inserted between the base 120 and the levitation unit cell 131 from outside. Accordingly, the upper surface (levitation surface) of the levitation unit cell 131 of the end part levitation unit 671 is a tilted surface that is higher toward outside. The height adjustment mechanism 1311 may include a leveling bolt or the like for adjusting height. The height of the levitation unit cell 131 on the outer side is changed by rotating a height adjustment screw provided at the height adjustment mechanism 1311. In this manner, the tilt angle of the levitation surface can be adjusted.

With this configuration, the levitation unit cell 131 ejects gas obliquely upward. Specifically, gas from the levitation unit cell 131 is ejected upward and toward the substrate center. The upper surface of the levitation unit cell 131 of the end part levitation unit 671 is a flat surface tilted from an XY plane. Gas is ejected in a direction orthogonal to the upper surface of the levitation unit cell 131.

### Base 120

The substrate 100 is levitated by gas ejected from the levitation unit 10. Thus, in a case where the size of the substrate 100 is large, gas accumulates between the substrate 100 and the levitation unit 10 in some cases. For example, in a case where the rough levitation regions 33 are sufficiently large for the substrate 100 and the levitation unit 30 cells 131 are disposed on the base 120 without gaps, a large amount of gas accumulates in an air gap between the substrate 100 and the levitation unit 10. In such a case, a dome phenomenon that the amount of levitation near the center of the substrate 100 is large and the amount of levitation at the end parts is extremely small potentially occurs.

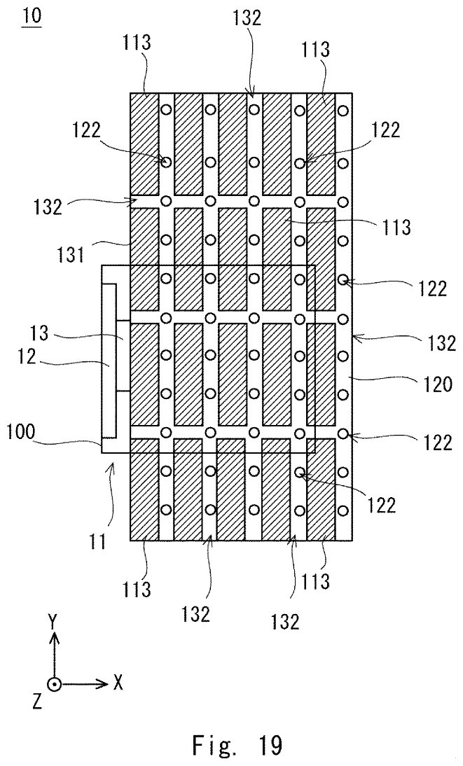

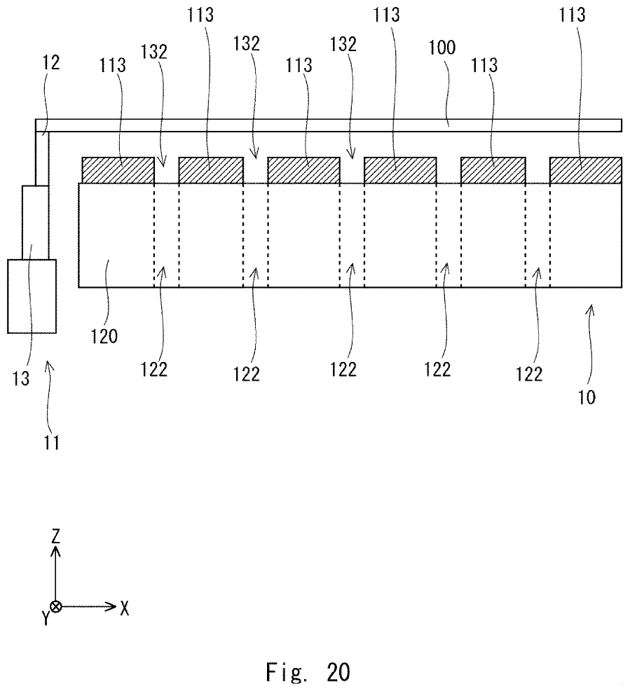

In such a case, the base 120 is preferably provided with through-holes (release holes) for releasing gas. A configuration example of the base 120 will be described below with reference to FIGS. 19 and 20. FIG. 19 is a top view schematically illustrating the configuration of the levitation unit 10. FIG. 20 is a side view schematically illustrating the configuration of the levitation unit 10. Note that, in FIGS. 19 and 20, a partial configuration of the levitation unit 10 is illustrated, and the configuration is simplified as appropriate.

Release holes 122 are provided at the base 120. Specifically, the release holes 122 are through-holes penetrating the base 120 in the Z direction. The release holes 122 are provided up to the gaps 132. Accordingly, the release holes 122 are exposed at the upper surface of the base 120.

In FIG. 19, a plurality of rough levitation units 113 are arrayed at predetermined intervals in the X direction and the Y direction. The rough levitation units 113 are arrayed in a two-dimensional array shape. The gaps 132 provided between the rough levitation units 113 are parallel to the X direction and the Y direction. In other words, the gaps 132 are formed in a lattice shape extending in the X direction and the Y direction.

A plurality of release holes 122 are formed in the gaps 132. The plurality of release holes 122 are arranged in an array shape extending in the X direction and the Y direction. With this configuration, gas between the substrate 100 and the levitation unit 10 can be released below the base 120 through the release holes 122. Accordingly, the dome phenomenon can be prevented and the substrate 100 can be conveyed with an appropriate amount of levitation.

### Transfer Operation of Substrate 100

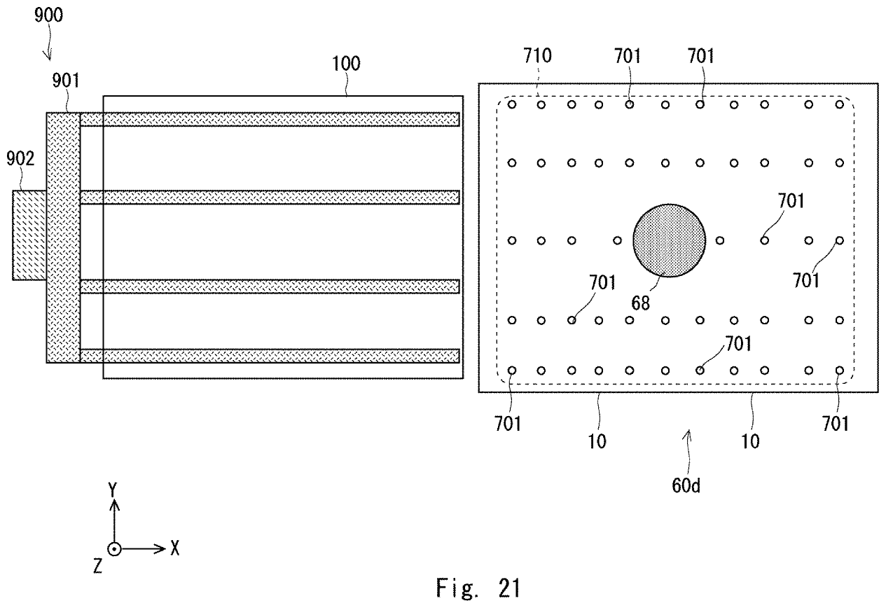

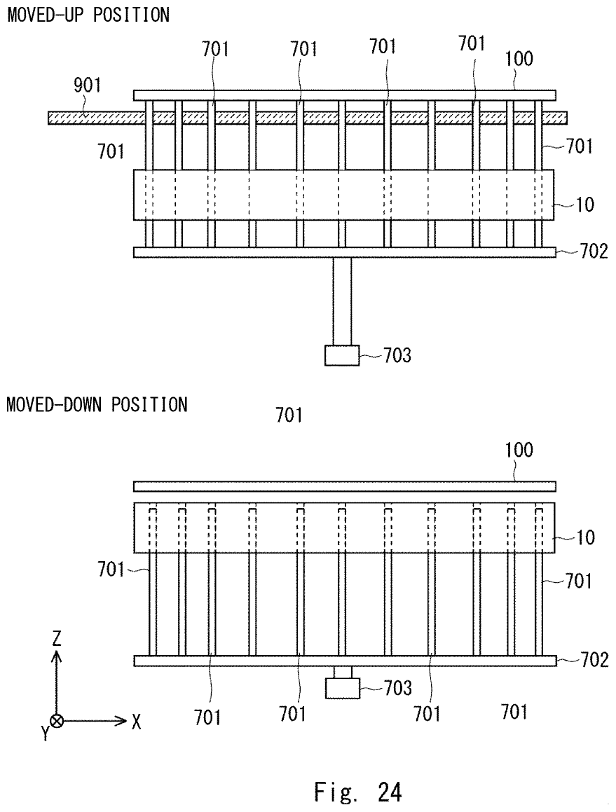

A mechanism that transfers the substrate 100 to the levitation unit 10 and operation thereof will be described next with reference to FIGS. 21 to 24. FIGS. 21 to 24 are schematic diagrams for description of operation for loading the substrate 100 into the fourth region 60d. FIGS. 21 to 23 are top views schematically illustrating the fourth region 60d and a transfer machine 900. FIG. 24 is a side view schematically illustrating upward-downward movement operation of the pusher pin 701.

As illustrated in FIG. 21, the transfer machine 900 is provided on the −x side of the fourth region 60d. The transfer machine 900 includes, for example, a hand 901 and an arm mechanism 902. The hand 901 holds the substrate 100. Specifically, the substrate 100 is placed on the hand 901. The arm mechanism 902 moves the hand 901. The arm mechanism 902 expands and contracts, for example, in the X direction. The hand 901 is transferred in the X direction by the arm mechanism 902. Thus, the X direction is a transfer direction. The −x direction is also referred to as a transfer machine side. The transfer machine 900 is a loader that transfers the substrate 100 to the fourth region 60d. Alternatively, the transfer machine 900 may be an unloader that transfers the substrate 100 from the fourth region 60d.

A plurality of pusher pins 701 are provided to be movable upward and downward in the fourth region 60d. The plurality of pusher pins 701 are upward-downward movement pins that move upward and downward. The pusher pins 701 move upward and downward to receive the substrate 100 from the hand 901. The plurality of pusher pins 701 are disposed at predetermined intervals in the X direction and the Y direction. The plurality of pusher pins 701 are dotted in a gas ejection region 710. For example, the pusher pins 701 vertically penetrate the levitation unit 10 (refer to FIG. 24). Specifically, the levitation unit 10 is provided with through-holes for providing the pusher pins 701. Alternatively, each pusher pin 701 may be disposed in the gap 132 between two adjacent levitation unit cells 131. Note that the shape of each pusher pin 701 is circular when viewed from top, but the planar shape of each pusher pin 701 is not limited to circular.

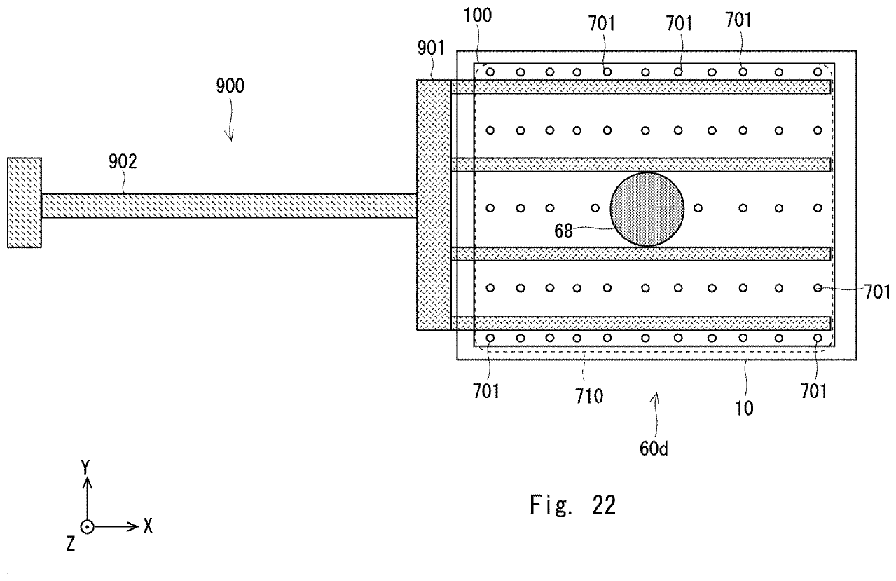

The rotary mechanism 68 is provided among the plurality of pusher pins 701. Specifically, the plurality of pusher pins 701 are disposed to avoid interfere with the rotary mechanism 68. Thus, to avoid the rotary mechanism 68, the interval of the pusher pins 701 is not equal in the vicinity of the rotary mechanism 68. Similarly, the plurality of pusher pins 701 are disposed to avoid interfere with the hand 901 (refer to FIG. 22). For example, the hand 901 has a comb shape including a plurality of nail parts to avoid contact with the plurality of pusher pins 701.

As illustrated in FIG. 24, the plurality of pusher pins 701 move upward and downward in cooperation. For example, each pusher pin 701 is a bar-shaped member extending in the Z direction and has a lower end coupled to an upward-downward movement base 702. The plurality of pusher pins 701 are fixed to one upward-downward movement base 702. Accordingly, the upward-downward movement base 702 supports the plurality of pusher pins 701.

An upward-downward movement mechanism 703 includes an actuator such as a motor or a cylinder and expands and contracts upward and downward. The upward-downward movement mechanism 703 moves the upward-downward movement base 702 upward and downward. The upward-downward movement mechanism 703 and the upward-downward movement base 702 are disposed on the lower side of the levitation unit 10. In FIG. 24, the heights of the pusher pins 701 when receiving the substrate 100 are illustrated as a moved-up position. In addition, the heights of the pusher pins 701 when moved downward and becoming lower than the upper surface of the levitation unit 10 is illustrated as a moved-down position. At the moved-down position, the substrate 100 is levitated above the levitation unit 10. The height of the substrate 100 at the moved-down position is referred to as a levitation height.

FIG. 21 illustrates a state before transfer, that is, a state in which the hand 901 holds the substrate 100. In FIG. 21, the substrate 100 and the hand 901 are positioned at a standby position outside the levitation unit 10. In this case, the pusher pins 701 are positioned at the moved-down position.

When the arm mechanism 902 moves the hand 901 in the +x direction from the standby position illustrated in FIG. 21, the hand 901 and the substrate 100 move to a loading position as illustrated in FIG. 22. In FIG. 22, the substrate 100 has moved to directly above the fourth region 60d. Specifically, in FIG. 22, a state in which the hand 901 and the substrate 100 have moved to the loading position above the fourth region 60d is illustrated.

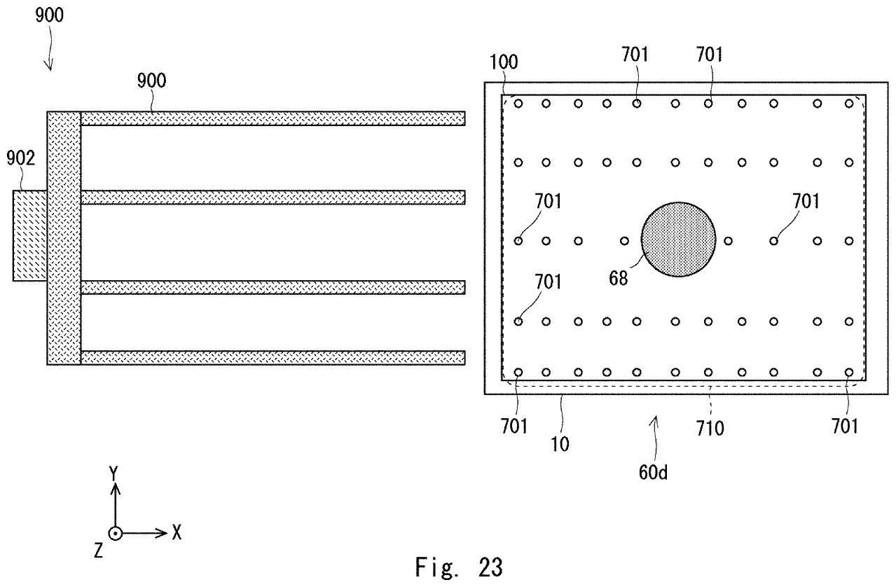

In the state illustrated in FIG. 22, the upward-downward movement mechanism 703 moves the upward-downward movement base 702 and the pusher pins 701 upward to the moved-up position (refer to FIG. 24). Accordingly, the substrate 100 contacts the distal ends of the pusher pins 701. The substrate 100 is lifted up from the hand 901 and handed over to the pusher pins 701. Accordingly, the substrate 100 is in contact with the pusher pins 701 but not in contact with the hand 901. Subsequently, the hand 901 is retracted from the fourth region 60d as illustrated in FIG. 23 as the hand 901 moves in the-x direction. Specifically, the hand 901 returns to the standby position.

After the hand 901 has returned to the standby position, the upward-downward movement mechanism 703 moves the upward-downward movement base 702 and the pusher pins 701 downward. The substrate 100 approaches the levitation unit 10 as the substrate 100 moves downward. The upper ends of the pusher pins 701 move to the lower side of the upper surface of the levitation unit 10. The substrate 100 moves down to the levitation height, and the substrate 100 becomes levitated above the levitation unit 10. In other words, the pusher pins 701 and the substrate 100 become a non-contact state.

In this manner, the end parts of the substrate 100 can be supported by using the pusher pins 701. Thus, deflection of the substrate 100 can be reduced. The substrate 100 can be appropriately supported during transfer of the substrate 100. The substrate 100 can be prevented from contacting the levitation unit 10 during transfer of the substrate 100 from outside. Note that operation opposite that described above may be performed in a case where the substrate 100 is transferred from the fourth region 60d. The substrate 100 can be appropriately transferred from the levitation unit 10.

By a transfer method according to the present embodiment, the substrate can be transferred to the above-described conveyance apparatus 600. The transfer method includes steps A1 to A3 described below.
(A1) step of moving a plurality of pusher pins upward to receive the substrate loaded into the loading region by the transfer machine 900.
(A2) step of moving the transfer machine 900 to the standby position outside the loading region.
(A3) step of moving the plurality of pusher pins downward to move the substrate 100 downward to the levitation height at the levitation unit 10.

### Pusher bar

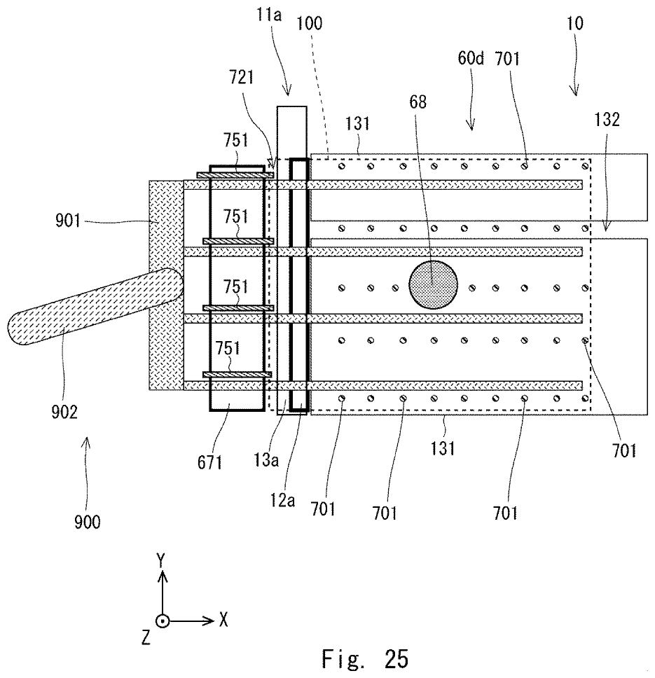

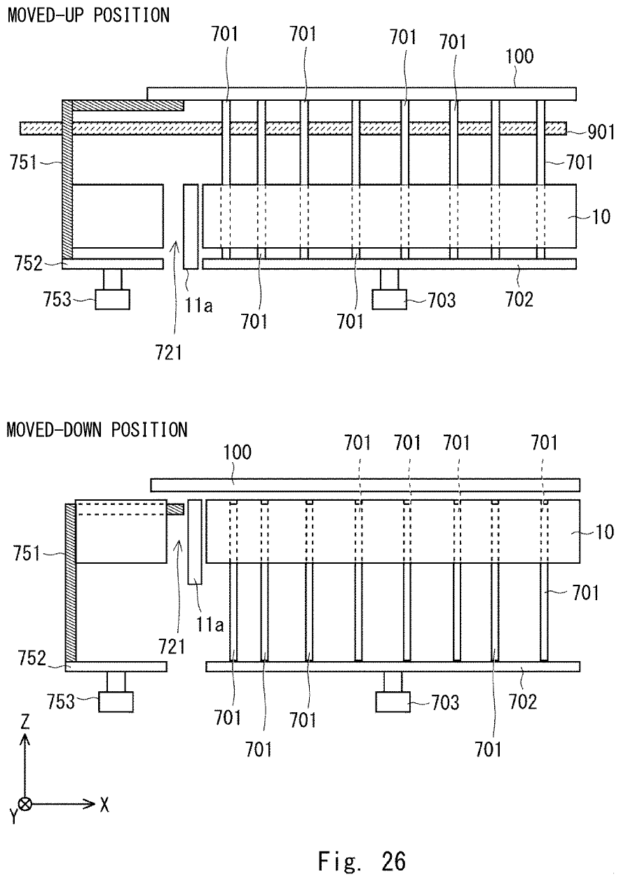

A mechanism using a pusher bar for loading the substrate in will be described below with reference to FIGS. 25 and 26. FIG. 25 is a top view schematically illustrating the loading mechanism, and FIG. 26 is a side view thereof. Pusher bars 751 are provided in addition to the pusher pins 701. Description of basic components other than the pusher bars 751 is omitted as appropriate. For example, the configuration and operation of the pusher pins 701 are the same as in the above description, and thus description thereof is omitted.

The end part levitation unit 671 is provided on the transfer machine 900 side of the levitation unit 10. In other words, the transfer machine 900 is provided on the −x side of the end part levitation unit 671. The conveyance unit 11a is provided in a space 721 between the end part levitation unit 671 and the levitation unit 10. As described above, the holding mechanism 12a of the conveyance unit 11a moves through the space 721 in the Y direction. Accordingly, the holding mechanism 12a passes between the end part levitation unit 671 and the levitation unit 10. The plurality of pusher pins 701 are provided at the levitation unit 10. The plurality of pusher pins 701 are disposed in through-holes of the levitation unit cells 131 or the gaps 132 between the levitation unit cells.

Since the conveyance unit 11a is provided in the space 721, a space for disposing the pusher pins 701 and the upward-downward movement mechanism is restricted in the space 721. Thus, the pusher bars 751 are provided on the transfer machine 900 side of the end part levitation unit 671. The pusher bars 751 extend in the X direction, that is, the transfer direction when viewed from top. The plurality of pusher bars 751 are arranged in a line at intervals in the Y direction. Note that four pusher bars 751 are provided at the conveyance apparatus 600 in FIG. 25, but the number of pusher bars 751 is not particularly limited. The pusher bars 751 are disposed to avoid interfere with the hand 901.

As illustrated in FIG. 26, the pusher bars 751 move upward and downward in coordination with the pusher pins 701. For example, at reception of the substrate 100, the pusher bars 751 and the pusher pins 701 move to the moved-up position. When the substrate 100 is moved downward to the levitation height, the pusher bars 751 and the pusher pins 701 move to the moved-down position. Each pusher bar 751 is an L-shaped member in a side view and includes a bar-shaped part extending in the X direction and a bar-shaped part extending in the Z direction.

The part of each pusher bar 751 extending in the Z direction is disposed on the −x side of the end part levitation unit 671. Each pusher bar 751 extends from the upper side of the end part levitation unit 671 to the lower side in the Z direction. Each pusher bar 751 has a lower end coupled to an upward-downward movement base 752. The plurality of pusher bars 751 are fixed to one upward-downward movement base 752. Accordingly, the upward-downward movement base 702 supports the plurality of pusher bars 751.

An upward-downward movement mechanism 753 including an actuator moves the upward-downward movement base 752 upward and downward. The upward-downward movement mechanism 753 expands and contracts upward and downward. The upward-downward movement mechanism 753 and the upward-downward movement base 752 are disposed on the lower side of the end part levitation unit 671. In FIG. 26, the heights of the pusher pins 701 and the pusher bars 751 when receiving the substrate 100 are illustrated as the moved-up position. In addition, the heights of the pusher pins 701 and the pusher bars 751 when moved downward and becoming lower than the upper surfaces of the levitation unit 10 and the end part levitation unit 671 are illustrated as the moved-down position.

The plurality of pusher bars 751 move upward and downward in cooperation through upward-downward movement operation of the upward-downward movement mechanism 753. In addition, the upward-downward movement mechanism 703 and the upward-downward movement mechanism 753 operate in cooperation. Accordingly, the pusher bars 751 move upward and downward in coordination with the pusher pins 701. Note that the upward-downward movement mechanism 753 and the upward-downward movement mechanism 703 are illustrated as separate bodies in FIG. 26, but the upward-downward movement mechanism 753 and the upward-downward movement mechanism 703 may be the same mechanism. Thus, the pusher pins 701 and the pusher bars 751 may be moved upward and downward with one actuator. In this case, the upward-downward movement base 752 and the upward-downward movement base 702 may be integrated. Alternatively, the upward-downward movement base 752 and the upward-downward movement base 702 may be coupled. Accordingly, the pusher pins 701 and the pusher bars 751 can be moved upward and downward with one actuator in cooperation.

The pusher bars 751 extend from the −x side of the end part levitation unit 671 to the +x side in the X direction. The distal end of each pusher bar 751 protrudes from an end part of the end part levitation unit on the +x side. Specifically, the distal end of each pusher bars 751 extends to the space 721 between the end part levitation unit 671 and the levitation unit 10. The distal end of each pusher bar 751 protrudes from the end part levitation unit 671 toward the +x side when viewed from top. The pusher bars 751 are disposed to avoid interference with the conveyance unit 11a. Specifically, the pusher bars 751 do not contact the holding mechanism 12a, the moving mechanism 13a, nor the like even when the conveyance unit 11a conveys the substrate 100 in the Y direction.

At the moved-up position, an end part of the substrate 100 is supported by the distal ends of the pusher bars 751 on the +x side. Specifically, the distal ends of the pusher bars 751 on the +x side contact the end part of the substrate 100 on the −x side. Accordingly, the pusher pins 701 and the pusher bars 751 can lift up the substrate 100 from the hand 901, and thus the substrate 100 can be handed over. The substrate 100 moves downward to the levitation height as the pusher bars 751 and the pusher pins 701 move downward.

The end part of the substrate 100 can be supported by using the pusher bars 751 extending in the X direction. Deflection of the substrate 100 can be reduced. The substrate 100 can be appropriately supported during transfer of the substrate 100. The substrate 100 can be prevented from contacting the levitation unit 10 during transfer of the substrate 100 from outside. Note that operation opposite that described above may be performed in a case where the substrate 100 is unloaded from the fourth region 60d. The substrate 100 can be appropriately transferred from the levitation unit 10 when the substrate is unloaded, as well.

Note that, in FIG. 25, the longitudinal direction of the rectangular substrate 100 is parallel to the transfer direction. Specifically, the substrate 100 is rectangular when viewed from top, the longitudinal direction of the substrate 100 is parallel to the X direction, and the transverse direction thereof is parallel to the Y direction. After the substrate 100 is transferred to the region 60d, the rotary mechanism 68 rotates the substrate 100 by 90° about the z axis (refer to FIG. 15). Accordingly, the substrate 100 is conveyed in the Y direction in a state in which the longitudinal direction of the substrate 100 is parallel to the Y direction. Thus, the rotary mechanism 68 may rotate the substrate 100 until conveyance starts after transfer. The longitudinal direction of the substrate 100 is not limited to a direction parallel to the transfer direction but may be a direction orthogonal thereto. Moreover, the longitudinal direction of the substrate 100 is not limited to a direction parallel to the longitudinal direction of the substrate 100 during conveyance in the Y direction but may be a direction orthogonal thereto.

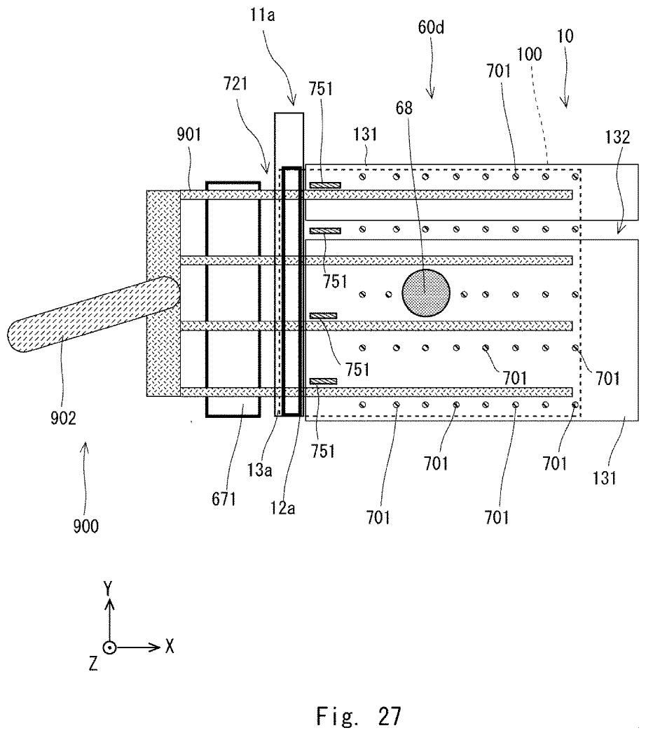

As a modification, the pusher bars 751 may be provided around an end part of the levitation unit 10 on the transfer machine side. This configuration of the modification will be described below with reference to FIG. 27. In FIG. 27, disposition of the pusher bars 751 is different from that in FIG. 25. Description of the other configuration than disposition of the pusher bars 751 is omitted as appropriate.

The pusher bars 751 are disposed in the fourth region 60d. In other words, the pusher bars 751 are disposed to overlap the levitation unit 10 when viewed from top. The distal ends of the pusher bars 751 do not protrude on the −x side of the levitation unit 10 in FIG. 27, but may protrude. The pusher bars 751 are disposed to avoid interference with the conveyance unit 11a.

With such a configuration as well, an end part of the substrate 100 can be supported. Deflection of the substrate 100 can be reduced. The substrate 100 can be appropriately supported during transfer of the substrate 100. The substrate 100 can be prevented from contacting the levitation unit 10 during transfer of the substrate 100 from outside. Note that the rotary mechanism 68 may be omitted.

In a method of transfer to the conveyance apparatus including pusher bars, the pusher bars 751 move upward and downward in coordination with the pusher pins 701 at the above-described steps (A1) and (A3).

The method of transfer to the conveyance apparatus including pusher bars includes steps B1 to B3 described below.
(B1) step of moving upward the plurality of pusher pins and pusher bars to receive a substrate loaded into the loading region by the transfer machine.
(B2) step of moving the transfer machine to the standby position outside the loading region.
(B3) step of moving downward the plurality of pusher pins and pusher bars to move the substrate downward to the levitation height of the levitation unit.

### Organic Light-Emitting Diode Display

A semiconductor apparatus including the above-described poly-silicon film is preferable for a thin film transistor (TFT) array substrate for electroluminescence display. Specifically, the poly-silicon film is used as a semiconductor layer including the source region, the channel region, and the drain region of a TFT.

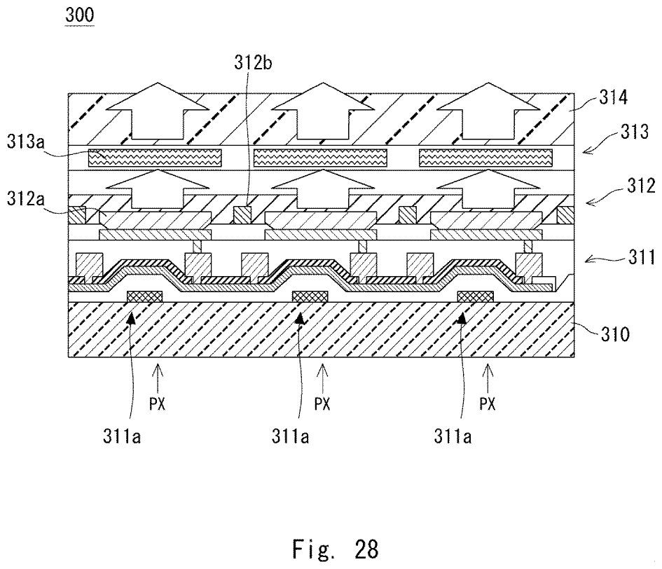

A configuration in which a semiconductor apparatus according to the present embodiment is applied to organic light-emitting diode display will be described below. FIG. 28 is a cross-sectional view illustrating pixel circuits of the organic light-emitting diode display in a simplified manner. This organic light-emitting diode display 300 illustrated in FIG. 28 is an active matrix display apparatus in which a TFT is disposed at each pixel PX.

The organic light-emitting diode display 300 includes a substrate 310, a TFT layer 311, an organic layer 312, a color filter layer 313, and a sealing substrate 314. A top-emission organic light-emitting diode display in which the sealing substrate 314 side is a viewing side is illustrated in FIG. 28. Note that the following description presents a configuration example of the organic light-emitting diode display, and the present embodiment is not limited to configurations described below. For example, the semiconductor apparatus according to the present embodiment may be used for a bottom-emission organic light-emitting diode display.

The substrate 310 is a glass substrate or a metal substrate. The TFT layer 311 is provided on the substrate 310. The TFT layer 311 includes a TFT 311a disposed at each pixel PX. The TFT layer 311 also includes a wire (not illustrated) connected to the TFT 311a, and the like. The TFT 311a, the wire, and the like constitute a pixel circuit.

The organic layer 312 is provided on the TFT layer 311. The organic layer 312 includes an organic electroluminescence light-emitting element 312a disposed for each pixel PX. The organic layer 312 is also provided with a partition 312b for separating the organic electroluminescence light-emitting elements 312a of each pair of pixels PX.

The color filter layer 313 is provided on the organic layer 312. The color filter layer 313 is provided with color filters 313a for performing color display. Specifically, a resin layer colored in red (R), green (G), or blue (B) is provided as the color filter 313a at each pixel PX.

The sealing substrate 314 is provided on the color filter layer 313. The sealing substrate 314 is a transparent substrate such as a glass substrate and provided to prevent degradation of the organic electroluminescence light-emitting elements of the organic layer 312.

Current that flows to each organic electroluminescence light-emitting elements 312a of the organic layer 312 changes with a display signal supplied to the pixel circuit. Thus, the amount of light emission at each pixel PX can be controlled by supplying a display signal in accordance with a display image to the pixel PX. Accordingly, a desired image can be displayed.

In an active matrix display apparatus such as an organic light-emitting diode display, each pixel PX is provided with one or more TFTs (for example, switching TFT or drive TFT). In addition, a semiconductor layer including a source region, a channel region, and a drain region is provided at each TFT of each pixel PX. The poly-silicon film according to the present embodiment is preferable for the semiconductor layer of each TFT. Specifically, in-plane variance of TFT characteristics can be reduced by using, as the semiconductor layer of a TFT array substrate, a poly-silicon film manufactured by the above-described manufacturing method. Thus, a display apparatus with excellent display characteristics can be manufactured at high productivity.

### Semiconductor Apparatus Manufacturing Method

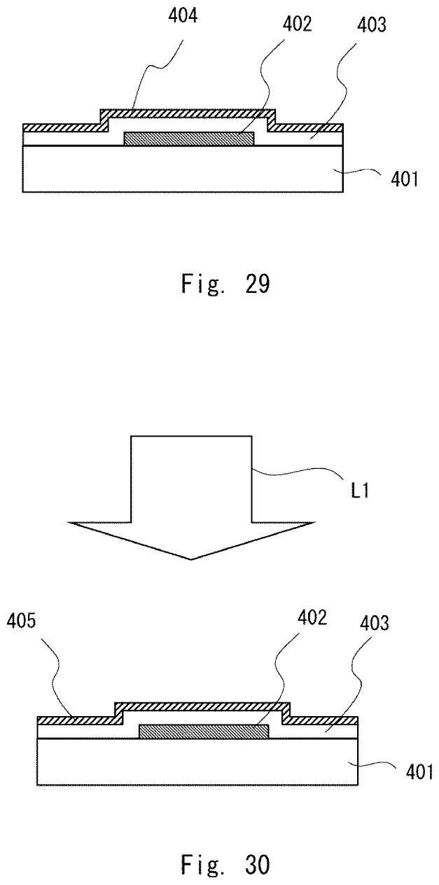

A semiconductor apparatus manufacturing method using the laser irradiation apparatus according to the present embodiment is preferable for manufacturing of a TFT array substrate. A method of manufacturing a semiconductor apparatus including a TFT will be described below with reference to FIGS. 29 and 30. FIGS. 29 and 30 are process cross-sectional views illustrating a semiconductor apparatus manufacturing process. The following description will be made on a method of manufacturing a semiconductor apparatus including an inverted staggered TFT. In FIGS. 29 and 30, a poly-silicon film formation process in the semiconductor manufacturing method is illustrated. Note that well-known methods can be used for other manufacturing processes, and thus description thereof is omitted.

As illustrated in FIG. 29, a gate electrode 402 is formed on a glass substrate 401. A gate insulating film 403 is formed on the gate electrode 402. An amorphous silicon film 404 is formed on the gate insulating film 403. The amorphous silicon film 404 is disposed to overlap the gate electrode 402 with the gate insulating film 403 interposed therebetween. For example, the gate insulating film 403 and the amorphous silicon film 404 are continuously deposited by a chemical vapor deposition (CVD) method.

Then, the glass substrate 401 on which the amorphous silicon film 404 is formed is conveyed to the above-described conveyance apparatus 600. A poly-silicon film 405 is formed by irradiating the amorphous silicon film 404 with a laser beam L1 as illustrated in FIG. 30. Specifically, the amorphous silicon film 404 is crystallized by the laser irradiation apparatus 1 illustrated in FIG. 1 and the like.

Accordingly, the poly-silicon film 405 in which silicon is crystallized is formed on the gate insulating film 403. The poly-silicon film 405 corresponds to the above-described poly-silicon film. Irradiation with the laser beam L1 is performed while the conveyance apparatus 600 conveys the glass substrate 401. Accordingly, the amorphous silicon film 404 is annealed and converted into the poly-silicon film 405.

Moreover, in the above description, the laser anneal apparatus according to the present embodiment irradiates an amorphous silicon film with a laser beam to form a poly-silicon film but may configured to irradiate an amorphous silicon film with a laser beam to form a microcrystalline silicon film. Further, a laser beam that performs anneal is not limited to a Nd:YAG laser. The method according to the present embodiment is also applicable to a laser anneal apparatus that crystallizes a thin film other than a silicon film. Specifically, the method according to the present embodiment is applicable to any laser anneal apparatus that irradiates an amorphous film with a laser beam to form a crystallized film. With the laser anneal apparatus according to the present embodiment, a substrate with a crystallized film can be appropriately reformed.

The semiconductor apparatus manufacturing method according to the present embodiment may include steps (s1) to (s3) described below.
(s1) step of forming an amorphous film on a substrate.
(s2) step of transferring the substrate on which the amorphous film is formed to a conveyance apparatus.
(s3) step of annealing the amorphous film by irradiating the substrate with a linear laser beam while conveying the substrate by using the conveyance apparatus so that the amorphous film is crystallized to form a crystallized film.

At step S2, the substrate 100 is loaded into the loading region by using the pusher pins 701 and the pusher bars 751 as described above. Accordingly, the end parts of the substrate can be supported, and thus the substrate can be prevented from contacting the levitation unit. Accordingly, a semiconductor apparatus can be manufactured at high productivity.

Alternatively, the semiconductor apparatus manufacturing method includes steps (t1) to (t3) described below.
(t1) step of forming an amorphous film on a substrate.
(t2) step of conveying the substrate on which the amorphous film is formed by using a conveyance apparatus.
(t3) step of annealing the amorphous film by irradiating the substrate being conveyed by the conveyance apparatus with a linear laser beam so that the amorphous film is crystallized to form a crystallized film.

The nozzle units 140 eject gas to the end parts of the substrate 100 being conveyed. The conveyance apparatus 600 does not necessarily need to include all of the above-described components. The transfer method, the conveyance method, and the manufacturing method do not necessarily need to include all of the above-described steps.

Note that the present invention is not limited to the above-described embodiment but can be modified as appropriate without departing from the scope thereof.

### REFERENCE SIGNS LIST

1 LASER IRRADIATION APPARATUS
10 LEVITATION UNIT
11 CONVEYANCE UNIT
12 HOLDING MECHANISM
13 MOVING MECHANISM
14 LASER IRRADIATION UNIT
15 LASER BEAM
15a IRRADIATION REGION
31 PRECISE LEVITATION REGION
32 SEMI-PRECISE LEVITATION REGION
33 ROUGH LEVITATION REGION
60a FIRST REGION
60b SECOND REGION
60c THIRD REGION
60d FOURTH REGION
60e PROCESS REGION
60f PASSING REGION
670 to 676 END PART LEVITATION UNIT
68 ROTARY MECHANISM
69a, 69b ALIGNMENT MECHANISM
100 SUBSTRATE
111 PRECISE LEVITATION UNIT
112 SEMI-PRECISE LEVITATION UNIT
113 ROUGH LEVITATION UNIT
131 LEVITATION UNIT CELL
1311 HEIGHT ADJUSTMENT MECHANISM
132 GAP
140 NOZZLE UNIT
141 BODY PART
142 EJECTION PART
145 CONNECTION PART
146 INTERNAL SPACE
300 ORGANIC LIGHT-EMITTING DIODE DISPLAY
310 SUBSTRATE
311 TFT LAYER
311a TFT
312 ORGANIC LAYER
312a ORGANIC ELECTROLUMINESCENCE LIGHT-EMITTING
ELEMENT
312b PARTITION
313 COLOR FILTER LAYER
313a COLOR FILTER (CF)
314 SEALING SUBSTRATE
401 GLASS SUBSTRATE
402 GATE ELECTRODE
403 GATE INSULATING FILM
404 AMORPHOUS SILICON FILM
405 POLY-SILICON FILM
671 to 676 END PART LEVITATION UNIT
701 PUSHER PIN
702 UPWARD-DOWNWARD MOVEMENT BASE
703 UPWARD-DOWNWARD MOVEMENT MECHANISM
710 EJECTION REGION
751 PUSHER BAR
752 UPWARD-DOWNWARD MOVEMENT BASE
753 UPWARD-DOWNWARD MOVEMENT MECHANISM
900 TRANSFER MACHINE
901 HAND
902 ARM MECHANISM
PX PIXEL

1. A conveyance apparatus configured to convey a substrate to irradiate the substrate with a linear laser beam, the conveyance apparatus comprising:
a levitation unit including a loading region into which a substrate is loaded, the levitation unit being configured to levitate the substrate over an upper surface of the levitation unit;
a first holding mechanism configured to hold the substrate over the levitation unit;
a first moving mechanism configured to move the first holding mechanism in a first conveyance direction tilted from a line direction of the laser beam when viewed from top to change an irradiation position of the laser beam on the substrate;
a plurality of pusher pins disposed in the loading region of the levitation unit and provided to be movable upward and downward to receive the substrate from a transfer machine transferring the substrate; and
a rotary mechanism disposed among the plurality of pusher pins in the loading region of the levitation unit and configured to rotate the substrate.

2. The conveyance apparatus according to claim 1, comprising:
an end part levitation unit disposed on the transfer machine side of the levitation unit and configured to levitate an end part of the substrate over an upper surface of the end part levitation unit;
a pusher bar extending in a transfer direction of the transfer machine and configured to move upward and downward in coordination with the pusher pins to receive the substrate from the transfer machine;
a second holding mechanism disposed between the levitation unit and the end part levitation unit and configured to hold the substrate; and
a second moving mechanism configured to move the second holding mechanism in a second conveyance direction so that the second holding mechanism moves between the levitation unit and the end part levitation unit.

3. A conveyance apparatus configured to convey a substrate to irradiate the substrate with a linear laser beam, the conveyance apparatus comprising:
a levitation unit including a loading region into which a substrate is loaded, the levitation unit being configured to levitate the substrate over an upper surface of the levitation unit;
a first holding mechanism configured to hold the substrate over the levitation unit;
a first moving mechanism configured to move the first holding mechanism in a first conveyance direction tilted from a line direction of the laser beam when viewed from top to change an irradiation position of the laser beam on the substrate;
a plurality of pusher pins disposed in the loading region of the levitation unit and provided to be movable upward and downward to receive the substrate from a transfer machine transferring the substrate;
an end part levitation unit disposed on the transfer machine side of the levitation unit and configured to levitate an end part of the substrate over an upper surface of the end part levitation unit;
a pusher bar extending in a transfer direction of the transfer machine and configured to move upward and downward in coordination with the pusher pins to receive the substrate from the transfer machine;
a second holding mechanism disposed between the levitation unit and the end part levitation unit and configured to hold the substrate; and
a second holding mechanism configured to move the second holding mechanism in a second conveyance direction so that the second holding mechanism moves between the levitation unit and the end part levitation unit.

4. The conveyance apparatus according to claim 2, wherein the pusher bar is provided at an end part of the end part levitation unit on the transfer machine side.

5. The conveyance apparatus according to claim 2, wherein the pusher bar is provided at an end part of the levitation unit on the transfer machine side.

6. The conveyance apparatus according to claim 2, wherein an upper surface of the end part levitation unit is lower than an upper surface of the levitation unit.

7. The conveyance apparatus according to claim 3, wherein
the levitation unit includes a plurality of levitation unit cells, and
a nozzle unit configured to eject gas upward to an end part of the substrate is provided in a gap between the levitation unit cells adjacent to each other.

8. The conveyance apparatus according to claim 7, wherein
the levitation unit includes a base that fixes the plurality of levitation unit cells, and
the base is provided with a through-hole reaching the gap between the levitation unit cells.

9. A conveyance apparatus configured to convey a substrate to irradiate the substrate with a linear laser beam, the conveyance apparatus comprising:
a levitation unit including a plurality of levitation unit cells and configured to levitate the substrate over an upper surface of the levitation unit;
a holding mechanism configured to hold the substrate over the levitation unit;
a moving mechanism configured to move the holding mechanism in a conveyance direction tilted from a line direction of the laser beam when viewed from top to change an irradiation position of the laser beam on the substrate; and
a nozzle unit provided in a gap between the levitation unit cells adjacent to each other and configured to eject gas toward an end part of the substrate.

10. The conveyance apparatus according to claim 7, wherein gas ejection from the nozzle unit is controlled in accordance with a conveyance position of the substrate.

11. The conveyance apparatus according to claim 7, wherein the nozzle unit ejects gas toward a corner of the substrate being rotated.

12. The conveyance apparatus according to claim 7, wherein
the plurality of levitation unit cells include
a first levitation unit cell having a longitudinal direction in a first direction when viewed from top, and
a second levitation unit cell having a longitudinal direction in a second direction orthogonal to the first direction when viewed from top, and
the nozzle unit is disposed in a gap between the first levitation unit cell and the second levitation unit cell.

13. The conveyance apparatus according to claim 7, wherein
the substrate is conveyed in a conveyance direction tilted from a direction orthogonal to the line direction of the laser beam, and
the nozzle unit is disposed in the gap parallel to the conveyance direction.

14. A transfer method of transferring a substrate to a conveyance apparatus configured to convey the substrate to irradiate the substrate with a linear laser beam, wherein
the conveyance apparatus includes
a levitation unit including a loading region into which a substrate is loaded, the levitation unit being configured to levitate the substrate over an upper surface of the levitation unit,
a first holding mechanism configured to hold the substrate over the levitation unit,
a first moving mechanism configured to move the first holding mechanism in a first conveyance direction tilted from a line direction of the laser beam when viewed from top to change an irradiation position of the laser beam on the substrate,
a plurality of pusher pins disposed in the loading region of the levitation unit and provided to be movable upward and downward to receive the substrate from a transfer machine transferring the substrate, and
a rotary mechanism disposed among the plurality of pusher pins in the loading region of the levitation unit and configured to rotate the substrate,
the transfer method includes
(A1) step of moving the plurality of pusher pins upward to receive a substrate loaded into the loading region by the transfer machine,
(A2) step of moving the transfer machine to a standby position outside the loading region, and
(A3) step of moving the plurality of pusher pins downward to move the substrate downward to a levitation height of the levitation unit.

15. The transfer method according to claim 14, wherein
the conveyance apparatus includes
an end part levitation unit disposed on the transfer machine side of the levitation unit and configured to levitate an end part of the substrate over an upper surface of the end part levitation unit,
a pusher bar extending in a transfer direction of the transfer machine and configured to move upward and downward in coordination with the pusher pins to receive the substrate from the transfer machine,
a second holding mechanism disposed between the levitation unit and the end part levitation unit and configured to hold the substrate, and
a second moving mechanism configured to move the second holding mechanism in a second conveyance direction so that the second holding mechanism moves between the levitation unit and the end part levitation unit, and
in the (A1) and (A3) steps, the pusher bar moves upward and downward in coordination with the pusher pins.

16. (canceled)

17. The transfer method according to claim 15, wherein the pusher bar is provided at an end part of the end part levitation unit on the transfer machine side.

18. The transfer method according to claim 15, wherein the pusher bar is provided at an end part of the levitation unit on the transfer machine side.

19. The transfer method according to claim 15, wherein an upper surface of the end part levitation unit is lower than an upper surface of the levitation unit.

20. The transfer method according to claim 14, wherein
the levitation unit includes a plurality of levitation unit cells, and
a nozzle unit configured to eject gas upward to an end part of the substrate is provided in a gap between the levitation unit cells adjacent to each other.

21 to 26. (canceled)

27. A semiconductor apparatus manufacturing method comprising:
(s1) step of forming an amorphous film on a substrate;
(s2) step of transferring the substrate on which the amorphous film is formed to a conveyance apparatus; and
(s3) step of annealing the amorphous film by irradiating the substrate with a linear laser beam while conveying the substrate by using the conveyance apparatus so that the amorphous film is crystallized to form a crystallized film, wherein
the conveyance apparatus includes
a levitation unit including a loading region into which a substrate is loaded, the levitation unit being configured to levitate the substrate over an upper surface of the levitation unit,
a first holding mechanism configured to hold the substrate over the levitation unit,
a first moving mechanism configured to move the first holding mechanism in a first conveyance direction tilted from a line direction of the laser beam when viewed from top to change an irradiation position of the laser beam on the substrate,
a plurality of pusher pins disposed in the loading region of the levitation unit and provided to be movable upward and downward to receive the substrate from a transfer machine transferring the substrate, and
a rotary mechanism disposed among the plurality of pusher pins in the loading region of the levitation unit and configured to rotate the substrate, and
(s2) the transferring step includes
(sa1) step of moving the plurality of pusher pins upward to receive a substrate loaded into the loading region by the transfer machine,
(sa2) step of moving the transfer machine to a standby position outside the loading region, and
(sa3) step of moving the plurality of pusher pins downward to move the substrate downward to a levitation height of the levitation unit.

28 to 39. (canceled)
